(19) United States
(12) Patent Application Publication
(10) Pub. No.: US 2012/0294457 A1
(43) Pub. Date: Nov. 22, 2012

(54) Audio System and Method of Using Adaptive Intelligence to Distinguish Information Content of Audio Signals and Control Signal Processing Function

(75) Inventors: Keith L. Chapman, Fountain Hills, AZ (US); Stanley J. Cotey, Mesa, AZ (US); Zhiyun Kuang, Gilbert, AZ (US)

(73) Assignee: FENDER MUSICAL INSTRUMENTS CORPORATION, Scottsdale, AZ (US)

(21) Appl. No.: 13/109,665

(22) Filed: May 17, 2011

(51) Int. Cl. H03G 5/00

(52) U.S. Cl. 381/98

(57) ABSTRACT

An audio system has a signal processor coupled for receiving an audio signal from a musical instrument or vocals. A time domain processor receives the audio signal and generates time domain parameters of the audio signal. A frequency domain processor receives the audio signal and generates frequency domain parameters of the audio signal. The audio signal is sampled and the time domain processor and frequency domain processor operate on a plurality of frames of the sampled audio signal. The time domain processor detects onset of a note of the sampled audio signal. A signature database has signature records each having time domain parameters and frequency domain parameters and control parameters. A recognition detector matches the time domain parameters and frequency domain parameters of the audio signal to a signature record of the signature database. The control parameters of the matching signature record control operation of the signal processor.

### FIELD OF THE INVENTION

The present invention relates in general to audio systems and, more particularly, to an audio system and method of using adaptive intelligence to distinguish dynamic content of an audio signal generated by a musical instrument and control a signal process function associated with the audio signal.

### BACKGROUND OF THE INVENTION

Audio sound systems are commonly used to amplify signals and reproduce audible sound. A sound generation source, such as a musical instrument, microphone, multi-media player, or other electronic device generates an electrical audio signal. The audio signal is routed to an audio amplifier, which controls the magnitude and performs other signal processing on the audio signal. The audio amplifier can perform filtering, modulation, distortion enhancement or reduction, sound effects, and other signal processing functions to enhance the tonal quality and frequency properties of the audio signal. The amplified audio signal is sent to a speaker to convert the electrical signal to audible sound and reproduce the sound generation source with enhancements introduced by the signal processing function.

Musical instruments have always been very popular in society providing entertainment, social interaction, self-expression, and a business and source of livelihood for many people. String instruments are especially popular because of their active playability, tonal properties, and portability. String instruments are enjoyable and yet challenging to play, have great sound qualities, and are easy to move about from one location to another.

In one example, the sound generation source may be an electric guitar or electric bass guitar, which is a well-known musical instrument. The guitar has an audio output which is connected to an audio amplifier. The output of the audio amplifier is connected to a speaker to generate audible musical sounds. In some cases, the audio amplifier and speaker are separate units. In other systems, the units are integrated into one portable chassis.

The electric guitar typically requires an audio amplifier to function. Other guitars use the amplifier to enhance the sound. The guitar audio amplifier provides features such as amplification, filtering, tone equalization, and sound effects. The user adjusts the knobs on the front panel of the audio amplifier to dial-in the desired volume, acoustics, and sound effects.

However, most if not all audio amplifiers are limited in the features that each can provide. High-end amplifiers provide more in the way of high quality sound reproduction and a variety of signal processing options, but are generally expensive and difficult to transport. The speaker is typically a separate unit from the amplifier in the high-end gear. A low-end amplifier may be more affordable and portable, but have limited sound enhancement features. There are few amplifiers for the low to medium end consumer market which provide full features, easy transportability, and low cost.

In audio reproduction, it is common to use a variety of signal processing techniques depending on the music and playing style to achieve better sound quality, playability, and otherwise enhance the artist's creativity, as well as the listener's enjoyment and appreciation of the composition. For example, guitar players use a large selection of audio amplifier settings and sound effects for different music styles. Bass players use different compressors and equalization settings to enhance sound quality. Singers use different reverb and equalization settings depending on the lyrics and melody of the song. Music producers use post processing effects to enhance the composition. For home and auto sound systems, the user may choose different reverb and equalization presets to optimize the reproduction of classical or rock music.

Audio amplifiers and other signal processing equipment, e.g., dedicated amplifier, pedal board, or sound rack, are typically controlled with front panel switches and control knobs. To accommodate the processing requirements for different musical styles, the user listens and manually selects the desired functions, such as amplification, filtering, tone equalization, and sound effects, by setting the switch positions and turning the control knobs. When changing playing styles or transitioning to another melody, the user must temporarily suspend play to make adjustments to the audio amplifier or other signal processing equipment. In some digital or analog instruments, the user can configure and save preferred settings as presets and then later manually select the saved settings or factory presets for the instrument.

In professional applications, a technician can make adjustments to the audio amplifier or other signal processing equipment while the artist is performing, but the synchronization between the artist and technician is usually less than ideal. As the artist changes attack on the strings or vocal content or starts a new composite, the technician must anticipate the artist action and make manual adjustments to the audio amplifier accordingly. In most if not all cases, the audio amplifier is rarely optimized to the musical sounds, at least not on a note-by-note basis.

### SUMMARY OF THE INVENTION

A need exists to dynamically control an audio amplifier or other signal processing equipment in realtime. Accordingly, in one embodiment, the present invention is an audio system comprising a signal processor coupled for receiving an audio signal. The dynamic content of the audio signal controls operation of the signal processor.

In another embodiment, the present invention is a method of controlling an audio system comprising the steps of providing a signal processor adapted for receiving an audio signal, and controlling operation of the signal processor using dynamic content of the audio signal.

In another embodiment, the present invention is an audio system comprising a signal processor coupled for receiving an audio signal. A time domain processor receives the audio signal and generates time domain parameters of the audio signal. A frequency domain processor receives the audio signal and generates frequency domain parameters of the audio signal. A signature database includes a plurality of signature records each having time domain parameters and frequency domain parameters and control parameters. A recognition detector matches the time domain parameters and frequency domain parameters of the audio signal to a signature record of the signature database. The control parameters of the matching signature record control operation of the signal processor.

In another embodiment, the present invention is a method of controlling an audio system comprising the steps of providing a signal processor adapted for receiving an audio signal, generating time domain parameters of the audio signal, generating frequency domain parameters of the audio signal, providing a signature database including a plurality of signature records each having time domain parameters and frequency domain parameters and control parameters, matching the time domain parameters and frequency domain parameters of the audio signal to a signature record of the signature database, and controlling operation of the signal processor based on the control parameters of the matching signature record.

### BRIEF DESCRIPTION OF THE DRAWINGS

FIG. 1 illustrates an audio sound source generating an audio signal and routing the audio signal through signal processing equipment to a speaker;

FIG. 2 illustrates a guitar connected to an audio sound system;

FIG. 3 illustrates a front view of the audio system enclosure with a front control panel;

FIG. 4 illustrates further detail of the front control panel of the audio system;

FIG. 5 illustrates an audio amplifier and speaker in separate enclosures;

FIG. 6 illustrates a block diagram of the audio amplifier with adaptive intelligence control;

FIGS. 7a-7b illustrate waveform plots of the audio signal;

FIG. 8 illustrates a block diagram of the frequency domain and time domain analysis block;

FIGS. 9a-9b illustrate time sequence frames of the sampled audio signal;

FIG. 10 illustrates a block diagram of the time domain analysis block;

FIG. 11 illustrates a block diagram of the time domain energy level isolation block in frequency bands;

FIG. 12 illustrates a block diagram of the time domain note detector block;

FIG. 13 illustrates a block diagram of the time domain attack detector;

FIG. 14 illustrates another embodiment of the time domain attack detector;

FIG. 15 illustrates a block diagram of the frequency domain analysis block;

FIG. 16 illustrates a block diagram of the frequency domain note detector block;

FIG. 17 illustrates a block diagram of the energy level isolation in frequency bins;

FIG. 18 illustrates a block diagram of the time domain attack detector;

FIG. 19 illustrates another embodiment of the frequency domain attack detector;

FIG. 20 illustrates the note signature database with parameter values, weighting values, and control parameters;

FIG. 21 illustrates a computer interface to the note signature database;

FIG. 22 illustrates a recognition detector for the runtime matrix and note signature database;

FIG. 23 illustrates an embodiment with the adaptive intelligence control implemented with separate signal processing equipment, audio amplifier, and speaker;

FIG. 24 illustrates the signal processing equipment implemented as a computer;

FIG. 25 illustrates a block diagram of the signal processing function within the computer;

FIG. 26 illustrates the signal processing equipment implemented as a pedal board;

FIG. 27 illustrates the signal processing equipment implemented as a signal processing rack;

FIG. 28 illustrates a vocal sound source routed to an audio amplifier and speaker;

FIG. 29 illustrates a block diagram of the audio amplifier with adaptive intelligence control on a frame-by-frame basis;

FIG. 30 illustrates a block diagram of the frequency domain and time domain analysis block on a frame-by-frame basis;

FIGS. 31a-31b illustrate time sequence frames of the sampled audio signal;

FIG. 32 illustrates a block diagram of the time domain analysis block;

FIG. 33 illustrates a block diagram of the time domain energy level isolation block in frequency bands;

FIG. 34 illustrates a block diagram of the frequency domain analysis block;

FIG. 35 illustrates the frame signature database with parameter value, weighting values, and control parameters;

FIG. 36 illustrates a computer interface to the frame signature database; and

FIG. 37 illustrates a recognition detector for the runtime matrix and frame signature database.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings.

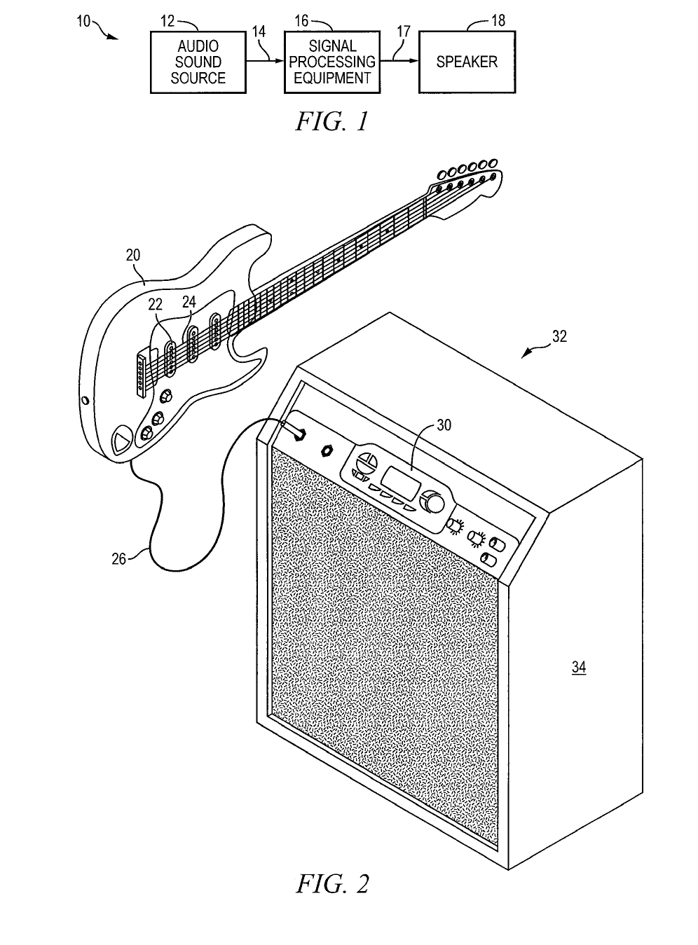

Referring to FIG. 1, an audio sound system 10 includes an audio sound source 12 which generates electric signals representative of sound content. Audio sound source 12 can be a musical instrument, audio microphone, multi-media player, or other device capable of generating electric signals representative of sound content. The musical instrument can be an electric guitar, bass guitar, violin, horn, brass, drums, wind instrument, string instrument, piano, electric keyboard, and percussions, just to name a few. The electrical signals from audio sound source 12 are routed through audio cable 14 to signal processing equipment 16 for signal conditioning and power amplification. Signal processing equipment 16 can be an audio amplifier, computer, pedal board, signal processing rack, or other equipment capable of performing signal processing functions on the audio signal. The signal processing function can include amplification, filtering, equalization, sound effects, and user-defined modules that adjust the power level and enhance the signal properties of the audio signal. The signal conditioned audio signal is routed through audio cable 17 to speaker 18 to reproduce the sound content of audio sound source 12 with the enhancements introduced into the audio signal by signal processing equipment 16.

FIG. 2 shows a musical instrument as audio sound source 12, in this case electric guitar 20. One or more pickups 22 are mounted under strings 24 of electric guitar 20 and convert string movement or vibration to electrical signals representative of the intended sounds from the vibrating strings. The electrical signals from guitar 20 are routed through audio cable 26 to an audio input jack on front control panel 30 of audio system 32 for signal processing and power amplification. Audio system 32 includes an audio amplifier and speaker co-located within enclosure 34. The signal conditioning provided by the audio amplifier may include amplification, filtering, equalization, sound effects, user-defined modules, and other signal processing functions that adjust the power level and enhance the signal properties of the audio signal. The signal conditioned audio signal is routed to the speaker within audio system 32. The power amplification increases or decreases the power level and signal strength of the audio signal to drive the speaker and reproduce the sound content intended by the vibrating strings 24 of electric guitar 20 with the enhancements introduced into the audio signal by the audio amplifier. Front control panel 30 includes a display and control knobs to allow the user to monitor and manually control various settings of audio system 32.

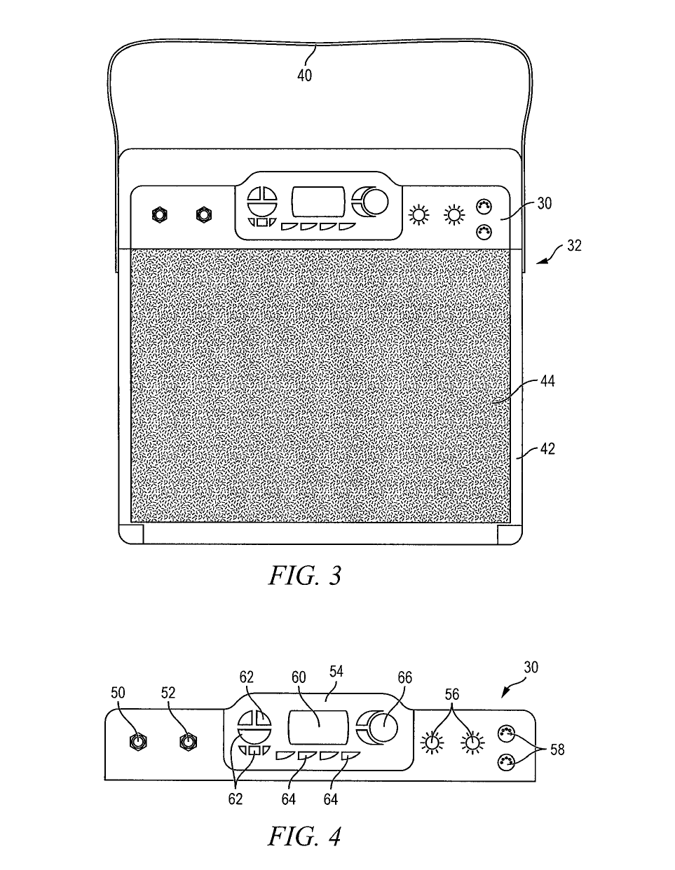

FIG. 3 shows a front view of audio system 32. An initial observation, the form factor and footprint of audio system 32 is designed for portable use and easy transportability. Audio system 32 measures about 13 inches high, 15 inches wide, and 7 inches deep, and weights in at about 16 pounds. A carry handle or strap 40 is provided to support the portability and ease of transport features. Audio system 32 has an enclosure 42 defined by an aluminum folded chassis, wood cabinet, black vinyl covering, front control panel, and cloth grille over speaker area 44. Front control panel 30 has connections for audio input, headphone, control buttons and knobs, liquid crystal display (LCD), and musical instrument digital interface (MIDI) input/output (I/O) jacks.

Further detail of front control panel 30 of audio system 32 is shown in FIG. 4. The external features of audio system 32 include audio input jack 50 for receiving audio cable 26 from guitar 20 or other musical instruments, headphone jack 52 for connecting to external headphones, programmable control panel 54, control knobs 56, and MIDI I/O jacks 58. Control knobs 56 are provided in addition to programmable control panel 54 for audio control functions which are frequently accessed by the user. In one embodiment, control knobs 56 provide user control of volume and tone. Additional control knobs 56 can control frequency response, equalization, and other sound control functions.

The programmable control panel 54 includes LCD 60, functional mode buttons 62, selection buttons 64, and adjustment knob or data wheel 66. The functional mode buttons 62 and selection buttons 64 are elastomeric rubber pads for soft touch and long life. Alternatively, the buttons may be hard plastic with tactic feedback micro-electronic switches. Audio system 32 is fully programmable, menu driven, and uses software to configure and control the sound reproduction features. The combination of functional mode buttons 62, selection buttons 64, and data wheel 66 provide control for the user interface over the different operational modes, access to menus for selecting and editing functions, and configuration of audio system 32. The programmable control panel 54 of audio system 32 may also include LEDs as indicators for sync/tap, tempo, save, record, and power functions.

In general, programmable control panel 54 is the user interface to the fully programmable, menu driven configuration and control of the electrical functions within audio system 32. LCD 60 changes with the user selections to provide many different configuration and operational menus and options. The operating modes may include startup and self-test, play, edit, utility, save, and tuner. In one operating mode, LCD 60 shows the playing mode of audio system 32. In another operating mode, LCD 60 displays the MIDI data transfer in process. In another operating mode, LCD 60 displays default setting and preset's. In yet another operating mode, LCD 60 displays a tuning meter.

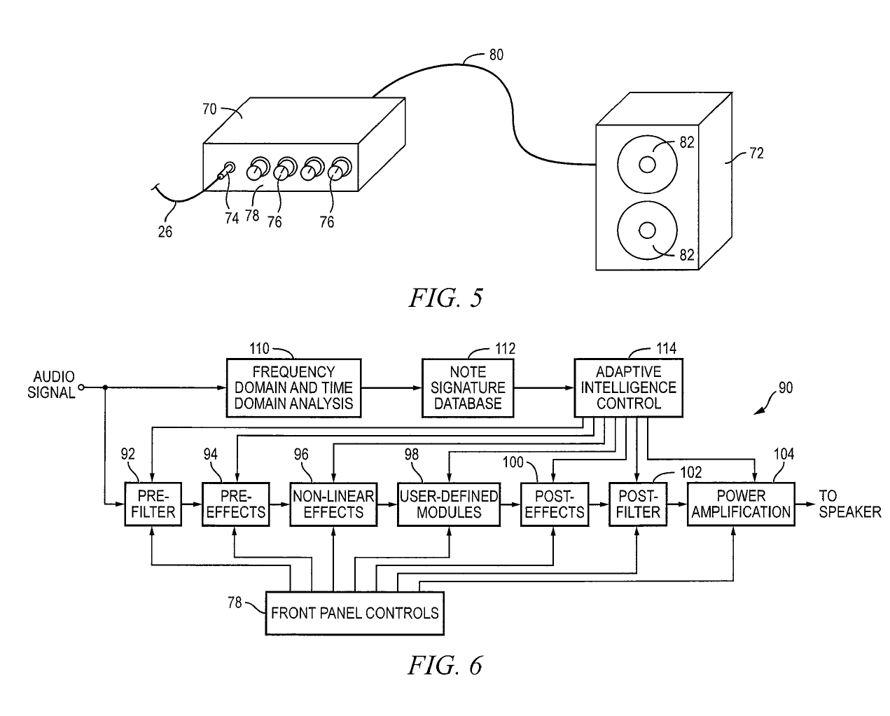

Turning to FIG. 5, the audio system can also be implemented with an audio amplifier contained within a first enclosure 70 and a speaker housed within a second separate enclosure 72. In this case, audio cable 26 from guitar 20 is routed to audio input jack 74, which is connected to the audio amplifier within enclosure 70 for power amplification and signal processing. Control knobs 76 on front control panel 78 of enclosure 70 allow the user to monitor and manually control various settings of the audio amplifier. Enclosure 70 is electrically connected by audio cable 80 to enclosure 72 to route the amplified and conditioned audio signal to speakers 82.

In audio reproduction, it is common to use a variety of signal processing techniques depending on the content of the audio source, e.g., performance or playing style, to achieve better sound quality, playability, and otherwise enhance the artist's creativity, as well as the listener's enjoyment and appreciation of the composition. For example, bass players use different compressors and equalization settings to enhance sound quality. Singers use different reverb and equalization settings depending on the lyrics and melody of the song. Music producers use post processing effects to enhance the composition. For home and auto sound systems, the user may choose different reverb and equalization presets to optimize the reproduction of classical or rock music.

FIG. 6 is a block diagram of audio amplifier 90 contained within audio system 32, or within audio amplifier enclosure 70 depending on the audio system configuration. Audio amplifier 90 receives audio signals from guitar 20 by way of audio cable 26. Audio amplifier 90 performs amplification and other signal processing functions, such as equalization, filtering, sound effects, and user-defined modules, on the audio signal to adjust the power level and otherwise enhance the signal properties for the listening experience.

To accommodate the signal processing requirements in accordance with the dynamic content of the audio source, audio amplifier 90 employs a dynamic adaptive intelligence feature involving frequency domain analysis and time domain analysis of the audio signal on a frame-by-frame basis and automatically and adaptively controls operation of the signal processing functions and settings within the audio amplifier to achieve an optimal sound reproduction. Each frame contains a predetermined number of samples of the audio signal, e.g., 32-1024 samples per frame. Each incoming frame of the audio signal is detected and analyzed on a frame-by-frame basis to determine its time domain and frequency domain content, and characteristics. The incoming frames of the audio signal are compared to a database of established or learned note signatures to determine a best match or closest correlation of the incoming frame to the database of note signatures. The note signatures from the database contain control parameters to configure the signal processing components of audio amplifier 90. The best matching note signature controls audio amplifier 90 in realtime to continuously and automatically make adjustments to the signal processing functions for an optimal sound reproduction. For example, based on the note signature, the amplification of the audio signal can be increased or decreased automatically for that particular frame of the audio signal. Presets and sound effects can be engaged or removed automatically for the note being played. The next frame in sequence may be associated with the same note which matches with the same note signature in the database, or the next frame in sequence may be associated with a different note which matches with a different corresponding note signature in the database. Each frame of the audio signal is recognized and matched to a note signature that in turn controls operation of the signal processing function within audio amplifier 90 for optimal sound reproduction. The signal processing function of audio amplifier 90 is adjusted in accordance with the best matching note signature corresponding to each individual incoming frame of the audio signal to enhance its reproduction.

The adaptive intelligence feature of audio amplifier 90 can learn attributes of each note of the audio signal and make adjustments based on user feedback. For example, if the user desires more or less amplification or equalization, or insertion of a particular sound effect for a given note, then audio amplifier builds those user preferences into the control parameters of the signal processing function to achieve the optimal sound reproduction. The database of note signatures with correlated control parameters makes realtime adjustments to the signal processing function. The user can define audio modules, effects, and settings which are integrated into the database of audio amplifier 90. With adaptive intelligence, audio amplifier 90 can detect and automatically apply tone modules and settings to the audio signal based on the present note signature. Audio amplifier 90 can interpolate between similar matching note signatures as necessary to select the best choice for the instant signal processing function.

Continuing with FIG. 6, audio amplifier 90 has a signal processing path for the audio signal, including pre-filter block 92, pre-effects block 94, non-linear effects block 96, user-defined modules 98, post-effects block 100, post-filter block 102, and power amplification block 104. Pre-filtering block 92 and post-filtering block 102 provide various filtering functions, such as low-pass filtering and bandpass filtering of the audio signal. The pre-filtering and post-filtering can include tone equalization functions over various frequency ranges to boost or attenuate the levels of specific frequencies without affecting neighboring frequencies, such as bass frequency adjustment and treble frequency adjustment. For example, the tone equalization may employ shelving equalization to boost or attenuate all frequencies above or below a target or fundamental frequency, bell equalization to boost or attenuate a narrow range of frequencies around a target or fundamental frequency, graphic equalization, or parametric equalization. Pre-effects block 94 and post-effects block 100 introduce sound effects into the audio signal, such as reverb, delays, chorus, wah, auto-volume, phase shifter, hum canceller, noise gate, vibrato, pitch-shifting, tremolo, and dynamic compression. Non-linear effects block 96 introduces non-linear effects into the audio signal, such as m-modeling, distortion, overdrive, fuzz, and modulation. User-defined module block 98 allows the user to define customized signal processing functions, such as adding accompanying instruments, vocals, and synthesizer options. Power amplification block 104 provides power amplification or attenuation of the audio signal. The post signal processing audio signal is routed to the speakers in audio system 32 or speakers 82 in enclosure 72.

The pre-filter block 92, pre-effects block 94, non-linear effects block 96, user-defined modules 98, post-effects block 100, post-filter block 102, and power amplification block 104 within audio amplifier 90 are selectable and controllable with front control panel 30 in FIG. 4 or front control panel 78 in FIG. 5. By turning knobs 76 on front control panel 78, or using LCD 60, functional mode buttons 62, selection buttons 64, and adjustment knob or data wheel 66 of programmable control panel 54, the user can directly control operation of the signal processing functions within audio amplifier 90.

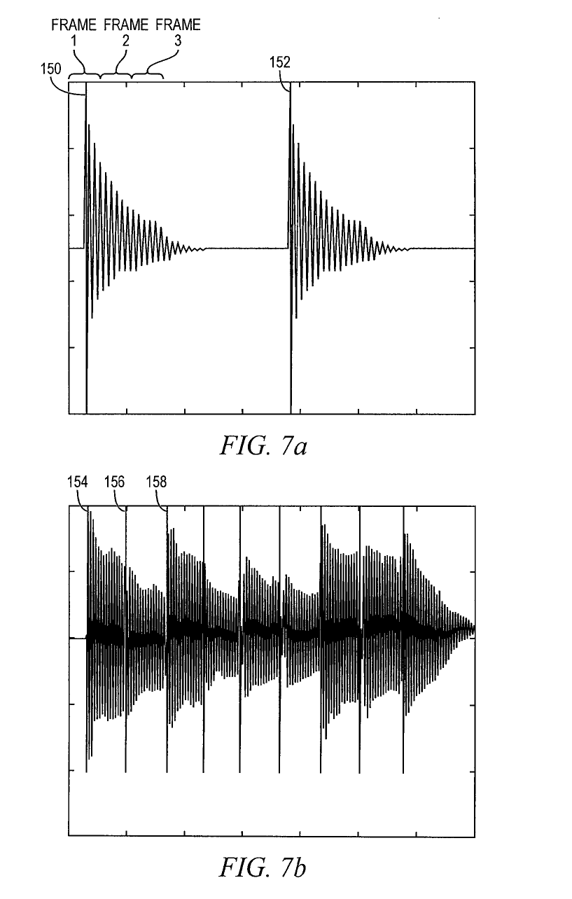

The audio signal can originate from a variety of audio sources, such as musical instruments or vocals. The instrument can be an electric guitar, bass guitar, violin, horn, brass, drums, wind instrument, piano, electric keyboard, percussions, or other instruments capable of generating electric signals representative of sound content. The audio signal can originate from an audio microphone handled by a male or female with voice ranges including soprano, mezzo-soprano, contralto, tenor, baritone, and bass. In the present discussion, the instrument is guitar 20, more specifically an electric bass guitar. When exciting strings 24 of bass guitar 20 with the musician's finger or guitar pick, the string begins a strong vibration or oscillation that is detected by pickup 22. The string vibration attenuates over time and returns to a stationary state, assuming the string is not excited again before the vibration ceases. The initial excitation of strings 24 is known as the attack phase. The attack phases is followed by a sustain phase during which the string vibration remains relatively strong. A decay phase follows the sustain phase as the string vibration attenuates and finally a release phase as the string returns to a stationary state. Pickup 22 converts string oscillations during the attack phase, sustain phase, decay phase, and release phase to an electrical signal, i.e., the analog audio signal, having an initial and then decaying amplitude at a fundamental frequency and harmonics of the fundamental. FIGS. 7a-7b illustrate amplitude responses of the audio signal in time domain corresponding to the attack phase and sustain phase and, depending on the figure, the decay phase and release phase of strings 24 in various playing modes. In FIG. 7b, the next attack phase begins before completing the previous decay phase or even beginning the release phase.

The artist can use a variety of playing styles when playing bass guitar 20. For example, the artist can place his or her hand near the neck pickup or bridge pickup and excite strings 24 with a finger pluck, known as “fingering style”, for modern pop, rhythm and blues, and avant-garde styles. The artist can slap strings 24 with the fingers or palm, known as “slap style”, for modern jazz, funk, rhythm and blues, and rock styles. The artist can excite strings 24 with the thumb, known as “thumb style”, for Motown rhythm and blues. The artist can tap strings 24 with two hands, each hand fretting notes, known as “tapping style”, for avant-garde and modern jazz styles. In other playing styles, artists are known to use fingering accessories such as a pick or stick. In each case, strings 24 vibrate with a particular amplitude and frequency and generate a unique audio signal in accordance with the string vibrations phases, such as shown in FIGS. 7a and 7b.

FIG. 6 further illustrates the dynamic adaptive intelligence control of audio amplifier 90. A primary purpose of the adaptive intelligence feature of audio amplifier 90 is to detect and isolate the frequency domain characteristics and time domain characteristics of the audio signal on a frame-by-frame basis and use that information to control operation of the signal processing function of the amplifier. The audio signal from audio cable 26 is routed to frequency domain and time domain analysis block 110. The output of block 110 is routed to note signature block 112, and the output of block 112 is routed to adaptive intelligence control block 114. The functions of blocks 110, 112, and 114 are discussed in sequence.

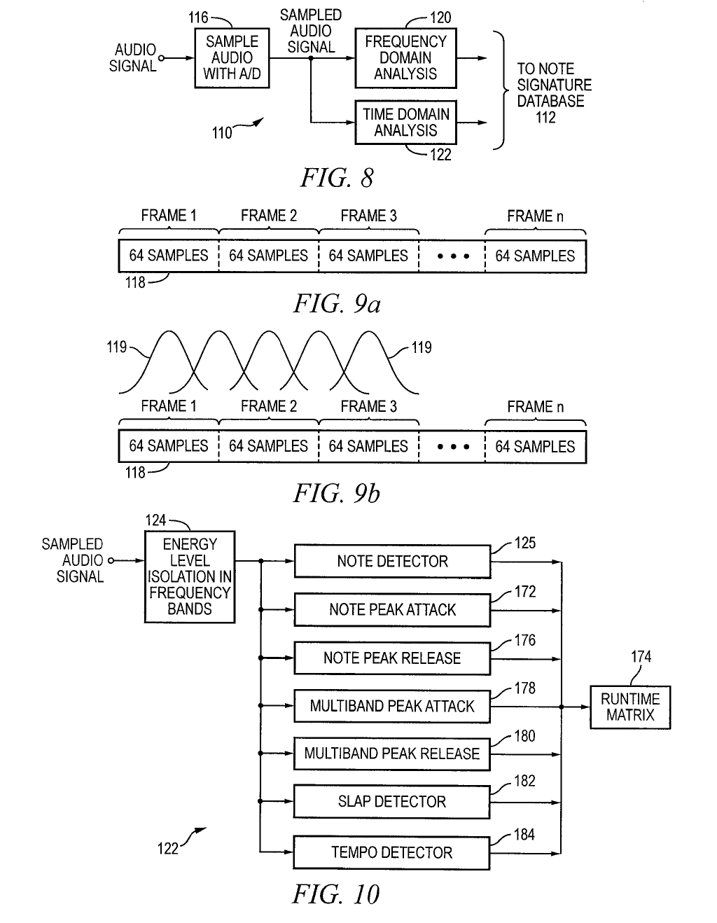

FIG. 8 illustrates further detail of frequency domain and time domain analysis block 110, including sample audio block 116, frequency domain analysis block 120, and time domain analysis block 122. The analog audio signal is presented to sample audio block 116. The sampled audio block 116 samples the analog audio signal, e.g., 32 to 1024 samples per second, using an analog-to-digital (A/D) converter. The sampled audio signal 118 is organized into a series of time progressive frames (frame 1 to frame n) each containing a predetermined number of samples of the audio signal. FIG. 9a shows frame 1 containing 64 samples of the audio signal 118 in time sequence, frame 2 containing the next 64 samples of the audio signal 118 in time sequence, frame 3 containing the next 64 samples of the audio signal 118 in time sequence, and so on through frame n containing 64 samples of the audio signal 118 in time sequence. FIG. 9b shows overlapping windows 119 of frames 1-n used in time domain to frequency domain conversion, as described in FIG. 15. The frames 1-n of the sampled audio signal 118 is routed to frequency domain analysis block 120 and time domain analysis block 122.

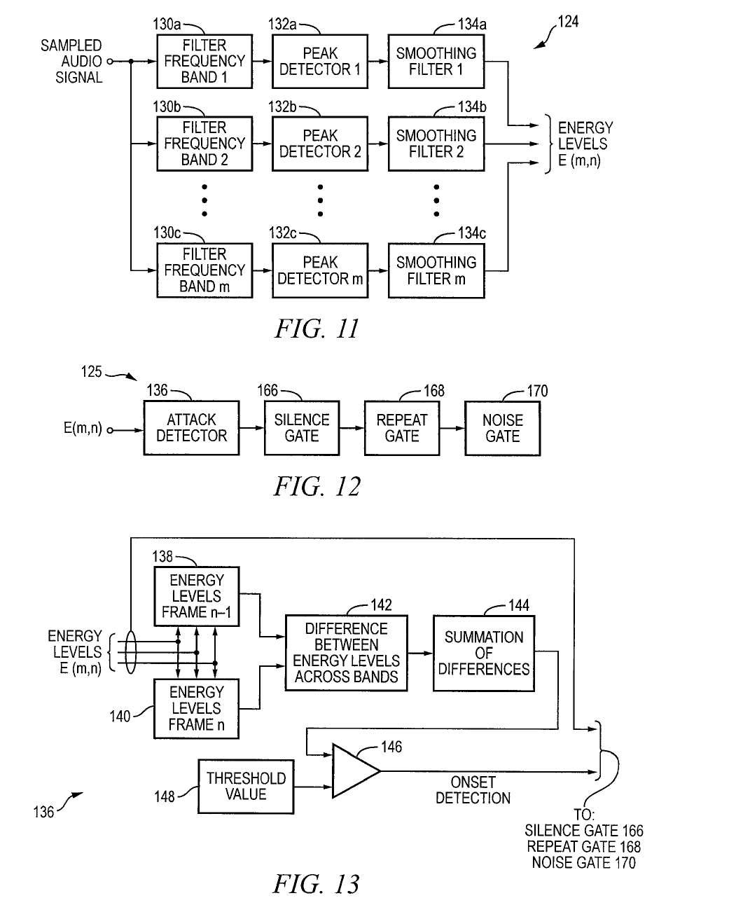

FIG. 10 illustrates further detail of time domain analysis block 122 including energy level isolation block 124 which isolates the energy level of each frame of the sampled audio signal 118 into multiple frequency bands. In FIG. 11, energy level isolation block 124 processes each frame of the sampled audio signal 118 in time sequence through filter frequency band 130a-130c to separate and isolate specific frequencies of the audio signal. The filter frequency bands 130a-130c can isolate specific frequency bands in the audio range 100-10000 Hz. In one embodiment, filter frequency band 130a is a bandpass filter with a pass band centered at 100 Hz, filter frequency band 130b is a bandpass filter with a pass band centered at 500 Hz, and filter frequency band 130c is a bandpass filter with a pass band centered at 1000 Hz. The output of filter frequency band 130a contains the energy level of the sampled audio signal 118 centered at 100 Hz. The output of filter frequency band 130b contains the energy level of the sampled audio signal 118 centered at 500 Hz. The output of filter frequency band 130c contains the energy level of the sampled audio signal 118 centered at 1000 Hz. The output of other filter frequency bands each contain the energy level of the sampled audio signal 118 for a specific band. Peak detector 132a monitors and stores peak energy levels of the sampled audio signal 118 centered at 100 Hz. Peak detector 132b monitors and stores peak energy levels of the sampled audio signal 118 centered at 500 Hz. Peak detector 132c monitors and stores peak energy levels of the sampled audio signal 118 centered at 1000 Hz. Smoothing filter 134a removes spurious components and otherwise stabilizes the peak energy levels of the sampled audio signal 118 centered at 100 Hz. Smoothing filter 134b removes spurious components and otherwise stabilizes the peak energy levels of the sampled audio signal 118 centered at 500 Hz. Smoothing filter 134c removes spurious components of the peak energy levels and otherwise stabilizes the sampled audio signal 118 centered at 1000 Hz. The output of smoothing filters 134a-134c is the energy level function E(m,n) for each frequency band 1-m in each frame n of the sampled audio signal 118.

The time domain analysis block 122 of FIG. 8 also includes note detector block 125, as shown in FIG. 10. Block 125 detects the onset of each note and provides for organization of the sampled audio signal into discrete segments, each segment beginning with the onset of the note, including a plurality of frames of the sampled audio signal, and concluding with the onset of the next note. In the present embodiment, each discrete segment of the sampled audio signal corresponds to a single note of music. Note detector block 125 associates the attack phase of strings 24 as the onset of a note. That is, the attack phase of the vibrating string 24 on guitar 20 coincides with the detection of a specific note. For other instruments, note detection is associated with a distinct physical act by the artist, e.g., pressing the key of a piano or electric keyboard, exciting the string of a harp, exhaling air into a horn while pressing one or more keys on the horn, or striking the face of a drum with a drumstick. In each case, note detector block 125 monitors the time domain dynamic content of the sampled audio signal 118 and identifies the onset of a note.

FIG. 12 shows further detail of note detector block 125 including attack detector 136. Once the energy level function E(m,n) is determined for each frequency band 1-m of the sampled audio signal 118, the energy levels 1-m of one frame n−1 are stored in block 138 of attack detector 136, as shown in FIG. 13. The energy levels of frequency bands 1-m for the next frame n of the sampled audio signal 118, as determined by filter frequency bands 130a-130c, peak detectors 132a-132c, and smoothing filters 134a-134c, are stored in block 140 of attack detector 136. Difference block 142 determines a difference between energy levels of corresponding bands of the present frame n and the previous frame n−1. For example, the energy level of frequency band 1 for frame n−1 is subtracted from the energy level of frequency band 1 for frame n. The energy level of frequency band 2 for frame n−1 is subtracted from the energy level of frequency band 2 for frame n. The energy level of frequency band m for frame n−1 is subtracted from the energy level of frequency band m for frame n. The difference in energy levels for each frequency band 1-m of frame n and frame n−1 are summed in summer 144.

Equation (1) provides another illustration of the operation of blocks 138-142.

g(m,n)=max(0,[E(m,n)/E(m,n−1)]−1) (1)

where:
g(m,n) is a maximum function of energy levels over
n frames of m frequency bands
E(m,n) is the energy level of frame n of frequency band m
E(m,n−1) is the energy level of frame n−1 of frequency band m

The function g(m,n) has a value for each frequency band 1-m and each frame 1-n. If the ratio of E(m,n)/E(m,n−1), i.e., the energy level of band m in frame n to the energy level of band m in frame n−1, is less than one, then [E(m,n)/E(m,n−1)]−1 is negative. The energy level of band m in frame n is not greater than the energy level of band m in frame n−1. The function g(m,n) is zero indicating no initiation of the attack phase and therefore no detection of the onset of a note. If the ratio of E(m,n)/E(m,n−1), i.e., the energy level of band m in frame n to the energy level of band m in frame n−1, is greater than one (say value of two), then [E(m,n)/E(m,n−1)]−1 is positive, i.e., value of one. The energy level of band m in frame n is greater than the energy level of band m in frame n−1. The function g(m,n) is the positive value of [E(m,n)/E(m,n−1)]−1 indicating initiation of the attack phase and a possible detection of the onset of a note.

Summer 144 accumulates the difference in energy levels E(m,n) of each frequency band 1-m of frame n and frame n−1. The onset of a note will occur when the total of the differences in energy levels E(m,n) across the entire monitored frequency bands 1-m for the sampled audio signal 118 exceeds a predetermined threshold value. Comparator 146 compares the output of summer 144 to a threshold value 148. If the output of summer 144 is greater than threshold value 148, then the accumulation of differences in the energy levels E(m,n) over the entire frequency spectrum for the sampled audio signal 118 exceeds the threshold value 148 and the onset of a note is detected in the instant frame n. If the output of summer 144 is less than threshold value 148, then no onset of a note is detected.

At the conclusion of each frame, attack detector 136 will have identified whether the instant frame contains the onset of a note, or whether the instant frame contains no onset of a note. For example, based on the summation of differences in energy levels E(m,n) of the sampled audio signal 118 over the entire spectrum of frequency bands 1-m exceeding threshold value 148, attack detector 136 may have identified frame 1 of FIG. 9a as containing the onset of a note, while frame 2 and frame 3 of FIG. 9a have no onset of a note. FIG. 7a illustrates the onset of a note at point 150 in frame 1 (based on the energy levels E(m,n) of the sampled audio signal within frequency bands 1-m) and no onset of a note in frame 2 or frame 3. FIG. 7a has another onset detection of a note at point 152. FIG. 7b shows onset detections of a note at points 154, 156, and 158.

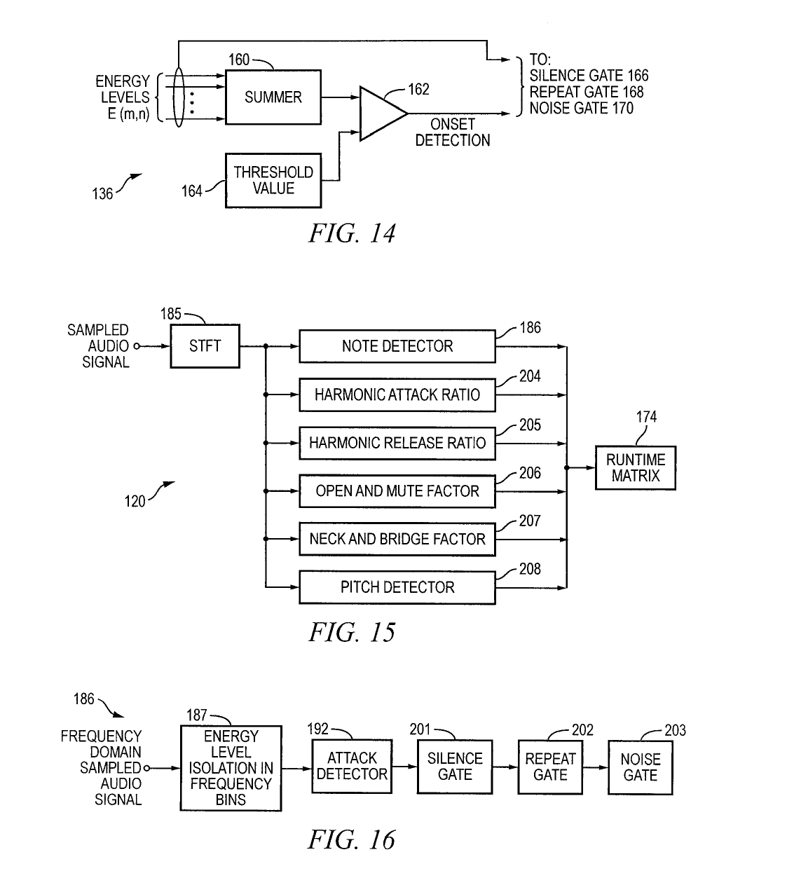

FIG. 14 illustrates another embodiment of attack detector 136 as directly summing the energy levels E(m,n) with summer 160. Summer 160 accumulates the energy levels E(m,n) of frame n in each frequency band 1-m for the sampled audio signal 118. The onset of a note will occur when the total of the energy levels E(m,n) across the entire monitored frequency bands 1-m for the sampled audio signal 118 exceeds a predetermined threshold value. Comparator 162 compares the output of summer 160 to a threshold value 164. If the output of summer 160 is greater than threshold value 164, then the accumulation of energy levels E(m,n) over the entire frequency spectrum for the sampled audio signal 118 exceeds the threshold value 164 and the onset of a note is detected in the instant frame n. If the output of summer 160 is less than threshold value 164, then no onset of a note is detected.

At the conclusion of each frame, attack detector 136 will have identified whether the instant frame contains the onset of a note, or whether the instant frame contains no onset of a note. For example, based on the summation of energy levels E(m,n) of the sampled audio signal 118 within frequency bands 1-m exceeding threshold value 164, attack detector 136 may have identified frame 1 of FIG. 9a as containing the onset of a note, while frame 2 and frame 3 of FIG. 9a have no onset of a note.

Returning to FIG. 12, attack detector 136 routes the onset detection of a note to silence gate 166, repeat gate 168, and noise gate 170. Not every onset detection of a note is genuine. Silence gate 166 monitors the energy levels E(m,n) of the sampled audio signal 118 after the onset detection of a note. If the energy levels E(m,n) of the sampled audio signal 118 after the onset detection of a note are low due to silence, e.g., −45 dB, then the energy levels E(m,n) of the sampled audio signal 118 that triggered the onset of a note are considered to be spurious and rejected. For example, the artist may have inadvertently touched one or more of strings 24 without intentionally playing a note or chord. The energy levels E(m,n) of the sampled audio signal 118 resulting from the inadvertent contact may have been sufficient to detect the onset of a note, but because playing does not continue, i.e., the energy levels E(m,n) of the sampled audio signal 118 after the onset detection of a note indicate silence, the onset detection is rejected.

Repeat gate 168 monitors the number of onset detections occurring within a time period. If multiple onsets of a note are detected within a repeat detection time period, e.g., 50 milliseconds (ms), then only the first onset detection is recorded. That is, any subsequent onset of a note that is detected, after the first onset detection, within the repeat detection time period is rejected.

Noise gate 170 monitors the energy levels E(m,n) of the sampled audio signal 118 about the onset detection of a note. If the energy levels E(m,n) of the sampled audio signal 118 about the onset detection of a note are generally in the low noise range, e.g., the energy levels E(m,n) are −90 dB, then the onset detection is considered suspect and rejected as unreliable.

The time domain analysis block 122 of FIG. 8 also includes note peak attack block 172, as shown in FIG. 10. Block 172 uses the energy function E(m,n) to determine the time from the onset detection of a note to the peak energy level of the note during the attack phase or sustain phase of the string vibration prior to the decay of the energy levels over all frequency bands 1-m, i.e., a summation of frequency bands 1-m. The onset detection of a note is determined by attack detector 136. The peak energy level is the maximum value of the energy function E(m,n) during the attack phase or sustain phase of the string vibration prior to the decay of the energy levels over all frequency bands 1-m. The peak energy levels are monitored frame-by-frame in peak detectors 132a-132c. The peak energy level may occur in the same frame as the onset detection or in a subsequent frame. The note peak attack is a time domain parameter or characteristic of each frame n for all frequency bands 1-m and is stored as a value in runtime matrix 174 on a frame-by-frame basis.

Note peak release block 176 uses the energy function E(m,n) to determine the time from the onset detection of a note to a lower energy level during the decay phase or release phase of the note over all frequency bands 1-m, i.e., a summation of frequency bands 1-m. The onset detection of a note is determined by attack detector 136. The lower energy levels are monitored frame-by-frame in peak detectors 132a-132c. In one embodiment, the lower energy level is −3 dB from the peak energy level over all frequency bands 1-m. The note peak release is a time domain parameter or characteristic of each frame n for all frequency bands 1-m and is stored as a value in runtime matrix 174 on a frame-by-frame basis.

Multiband peak attack block 178 uses the energy function E(m,n) to determine the time from the onset detection of a note to the peak energy level of the note during the attack phase or sustain phase of the string vibration prior to the decay of the energy levels for each specific frequency band 1-m. The onset detection of a note is determined by attack detector 136. The peak energy level is the maximum value during the attack phase or sustain phase of the string vibration prior to the decay of the energy levels in each specific frequency band 1-m. The peak energy level is monitored frame-by-frame in peak detectors 132a-132c. The peak energy level may occur in the same frame as the onset detection or in a subsequent frame. The multiband peak attack is a time domain parameter or characteristic of each frame n for each frequency band 1-m and is stored as a value in runtime matrix 174 on a frame-by-frame basis.

Multiband peak release block 180 uses the energy function E(m,n) to determine the time from the onset detection of a note to a lower energy level during the decay phase or release phase of the note in each specific frequency band 1-m. The onset detection of a note is determined by attack detector 136. The lower energy level is monitored frame-by-frame in peak detectors 132a-132c. In one embodiment, the lower energy level is −3 dB from the peak energy level in each frequency band 1-m. The multiband peak release is a time domain parameter or characteristic of each frame n for each frequency band 1-m and is stored as a value in runtime matrix 174 on a frame-by-frame basis.

Slap detector 182 monitors the energy function E(m,n) in each frame 1-n over frequency bands 1-m to determine the occurrence of a slap style event, i.e., the artist has slapped strings 24 with his or her fingers or palm. A slap event is characterized by a sharp spike in the energy level during a frame in the attack phase of the note. For example, a slap event causes a 6 dB spike in energy level over and above the energy level in the next frame in the attack phase. The 6 dB spike in energy level is interpreted as a slap event. The slap detector is a time domain parameter or characteristic of each frame n for all frequency bands 1-m and is stored as a value in runtime matrix 174 on a frame-by-frame basis.

Tempo detector 184 monitors the energy function E(m,n) in each frame 1-n over frequency bands 1-m to determine the time interval between onset detection of adjacent notes, i.e., the duration of each note. The tempo detector is a time domain parameter or characteristic of each frame n for all frequency bands 1-m and is stored as a value in runtime matrix 174 on a frame-by-frame basis.

The frequency domain analysis block 120 in FIG. 8 includes STFT block 185, as shown in FIG. 15. Block 185 performs a time domain to frequency domain conversion on a frame-by-frame basis of the sampled audio signal 118 using a constant overlap adds (COLA) short time Fourier transform (STFT) or other fast Fourier transform (FFT). The COLA STFT 185 performs time domain to frequency domain conversion using overlap analysis windows 119, as shown in FIG. 9b. The sampling windows 119 overlap by a predetermined number of samples of the audio signal, known as hop size, for additional sample points in the COLA STFT analysis to ensure that data is weighted equally in successive frames. Equation (2) provides a general format of the time domain to frequency domain conversion on the sampled audio signal 118.

$${X}_{m} ( k ) = {\sum }_{n = 0}^{N - 1} x ( n ) {e}^{- j 2 π \frac{k}{N} n} \qquad ( 2 )$$

where:
Xₘ is the audio signal in frequency domain
x(n) is the mth frame audio input signal
m is the current number of frame
k is the frequency bin
N is the STFT size

The frequency domain analysis block 120 of FIG. 8 also includes note detector block 186, as shown in FIG. 15. Once the sampled audio signal 118 is in frequency domain, block 186 detects the onset of each note and provides for organization of the sampled audio signal into discrete segments, each segment beginning with the onset of the note, including a plurality of frames of the sampled audio signal, and concluding with the onset of the next note. In the present embodiment, each discrete segment of the sampled audio signal 118 corresponds to a single note of music. Note detector block 186 associates the attack phase of string 24 as the onset of a note. That is, the attack phase of the vibrating string 24 on guitar 20 coincides with the detection of a specific note. For other instruments, note detection is associated with a distinct physical act by the artist, e.g., pressing the key of a piano or electric keyboard, exciting the string of a harp, exhaling air into a horn while pressing one or more keys on the horn, or striking the face of a drum with a drumstick. In each case, note detector block 186 monitors the frequency domain dynamic content of the sampled audio signal 118 and identifies the onset of a note.

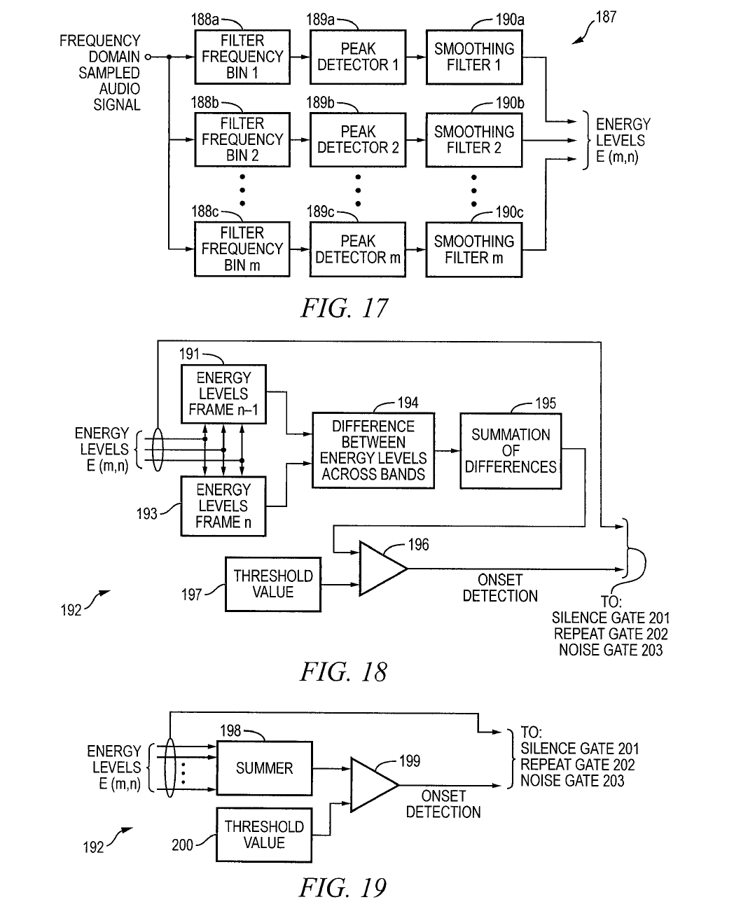

FIG. 16 shows further detail of frequency domain note detector block 186 including energy level isolation block 187 which isolates the energy level of each frame of the sampled audio signal 118 into multiple frequency bins. In FIG. 17, energy level isolation block 187 processes each frame of the sampled audio signal 118 in time sequence through filter frequency bins 188a-188c to separate and isolate specific frequencies of the audio signal. The filter frequency bins 188a-188c can isolate specific frequency bands in the audio range 100-10000 Hz. In one embodiment, filter frequency bin 188a is centered at 100 Hz, filter frequency bin 188b is centered at 500 Hz, and filter frequency bin 188c is centered at 1000 Hz. The output of filter frequency bin 188a contains the energy level of the sampled audio signal 118 centered at 100 Hz. The output of filter frequency bin 188b contains the energy level of the sampled audio signal 118 centered at 500 Hz. The output of filter frequency bin 188c contains the energy level of the sampled audio signal 118 centered at 1000 Hz. The output of other filter frequency bins each contain the energy level of the sampled audio signal 118 for a given specific band. Peak detector 189a monitors and stores the peak energy levels of the sampled audio signal 118 centered at 100 Hz. Peak detector 189b monitors and stores the peak energy levels of the sampled audio signal 118 centered at 500 Hz. Peak detector 189c monitors and stores the peak energy levels of the sampled audio signal 118 centered at 1000 Hz. Smoothing filter 190a removes spurious components and otherwise stabilizes the peak energy levels of the sampled audio signal 118 centered at 100 Hz. Smoothing filter 190b removes spurious components and otherwise stabilizes the peak energy levels of the sampled audio signal 118 centered at 500 Hz. Smoothing filter 190c removes spurious components, of the peak energy levels and otherwise stabilizes the sampled audio signal 118 centered at 1000 Hz. The output of smoothing filters 190a-190c is the energy level function E(m,n) for each frame n in each frequency bin 1-m of the sampled audio signal 118.

The energy levels E(m,n) of one frame n−1 are stored in block 191 of attack detector 192, as shown in FIG. 18. The energy levels of each frequency bin 1-m for the next frame n of the sampled audio signal 118, as determined by filter frequency bins 188a-188c, peak detectors 189a-189c, and smoothing filters 190a-190c, are stored in block 193 of attack detector 192. Difference block 194 determines a difference between energy levels of corresponding bins of the present frame n and the previous frame n−1. For example, the energy level of frequency bin 1 for frame n−1 is subtracted from the energy level of frequency bin 1 for frame n. The energy level of frequency bin 2 for frame n−1 is subtracted from the energy level of frequency bin 2 for frame n. The energy level of frequency bin m for frame n−1 is subtracted from the energy level of frequency bin m for frame n. The difference in energy levels for each frequency bin 1-m of frame n and frame n−1 are summed in summer 195.

Equation (1) provides another illustration of the operation of blocks 191-194. The function g(m,n) has a value for each frequency bin 1-m and each frame 1-n. If the ratio of E(m,n)/E(m,n−1), i.e., the energy level of bin m in frame n to the energy level of bin m in frame n−1, is less than one, then [E(m,n)/E(m,n−1)]−1 is negative. The energy level of bin m in frame n is not greater than the energy level of bin m in frame n−1. The function g(m,n) is zero indicating no initiation of the attack phase and therefore no detection of the onset of a note. If the ratio of E(m,n)/E(m,n−1), i.e., the energy level of bin m in frame n to the energy level of bin m in frame n−1, is greater than one (say value of two), then [E(m,n)/E(m,n−1)]−1 is positive, i.e., value of one. The energy level of bin m in frame n is greater than the energy level of bin m in frame n−1. The function g(m,n) is the positive value of [E(m,n)/E(m,n−1)]−1 indicating initiation of the attack phase and a possible detection of the onset of a note.

Summer 195 accumulates the difference in energy levels E(m,n) of each frequency bin 1-m of frame n and frame n−1. The onset of a note will occur when the total of the differences in energy levels E(m,n) across the entire monitored frequency bins 1-m for the sampled audio signal 118 exceeds a predetermined threshold value. Comparator 196 compares the output of summer 195 to a threshold value 197. If the output of summer 195 is greater than threshold value 197, then the accumulation of differences in energy levels E(m,n) over the entire frequency spectrum for the sampled audio signal 118 exceeds the threshold value 197 and the onset of a note is detected in the instant frame n. If the output of summer 195 is less than threshold value 197, then no onset of a note is detected.

At the conclusion of each frame, attack detector 192 will have identified whether the instant frame contains the onset of a note, or whether the instant frame contains no onset of a note. For example, based on the summation of differences in energy levels E(m,n) of the sampled audio signal 118 over the entire spectrum of frequency bins 1-m exceeding threshold value 197, attack detector 192 may have identified frame 1 of FIG. 9a as containing the onset of a note, while frame 2 and frame 3 of FIG. 9a have no onset of a note. FIG. 7a illustrates the onset of a note at point 150 in frame 1 (based on the energy levels E(m,n) of the sampled audio signal within frequency bins 1-m) and no onset of a note in frame 2 or frame 3. FIG. 7a has another onset detection of a note at point 152. FIG. 7b shows onset detections of a note at points 154, 156, and 158.

FIG. 19 illustrates another embodiment of attack detector 192 as directly summing the energy levels E(m,n) with summer 198. Summer 198 accumulates the energy levels E(m,n) of each frame 1-n and each frequency bin 1-m for the sampled audio signal 118. The onset of a note will occur when the total of the energy levels E(m,n) across the entire monitored frequency bins 1-m for the sampled audio signal 118 exceeds a predetermined threshold value. Comparator 199 compares the output of summer 198 to a threshold value 200. If the output of summer 198 is greater than threshold value 200, then the accumulation of energy levels E(m,n) over the entire frequency spectrum for the sampled audio signal 118 exceeds the threshold value 200 and the onset of a note is detected in the instant frame n. If the output of summer 198 is less than threshold value 200, then no onset of a note is detected.

At the conclusion of each frame, attack detector 192 will have identified whether the instant frame contains the onset of a note, or whether the instant frame contains no onset of a note. For example, based on the summation of energy levels E(m,n) of the sampled audio signal 118 within frequency bins 1-m exceeding threshold value 200, attack detector 192 may have identified frame 1 of FIG. 9a as containing the onset of a note, while frame 2 and frame 3 of FIG. 9a have no onset of a note.

Returning to FIG. 16, attack detector 192 routes the onset detection of a note to silence gate 201, repeat gate 202, and noise gate 203. Not every onset detection of a note is genuine. Silence gate 201 monitors the energy levels E(m,n) of the sampled audio signal 118 after the onset detection of a note. If the energy levels E(m,n) of the sampled audio signal 118 after the onset detection of a note are low due to silence, e.g., −45 dB, then the energy levels E(m,n) of the sampled audio signal 118 that triggered the onset of a note are considered to be spurious and rejected. For example, the artist may have inadvertently touched one or more of strings 24 without intentionally playing a note or chord. The energy levels E(m,n) of the sampled audio signal 118 resulting from the inadvertent contact may have been sufficient to detect the onset of a note, but because playing does not continue, i.e., the energy levels E(m,n) of the sampled audio signal 118 after the onset detection of a note indicate silence, the onset detection is rejected.

Repeat gate 202 monitors the number of onset detections occurring within a time period. If multiple onsets of a note are detected within the repeat detection time period, e.g., 50 ms, then only the first onset detection is recorded. That is, any subsequent onset of a note that is detected, after the first onset detection, within the repeat detection time period is rejected.

Noise gate 203 monitors the energy levels E(m,n) of the sampled audio signal 118 about the onset detection of a note. If the energy levels E(m,n) of the sampled audio signal 118 about the onset detection of a note are generally in the low noise range, e.g., the energy levels E(m,n) are −90 dB, then the onset detection is considered suspect and rejected as unreliable.

Returning to FIG. 15, harmonic attack ratio block 204 determines a ratio of the energy levels of various frequency harmonics in the frequency domain sampled audio signal 118 during the attack phase or sustain phase of the note on a frame-by-frame basis. Alternatively, the harmonic attack ratio monitors a fundamental frequency and harmonic of the fundamental. In one embodiment, to monitor a slap style, the frequency domain energy level of the sampled audio signal 118 is measured at 200 Hz fundamental of the slap and 4000 Hz harmonic of the fundamental during the attack phase of the note. The ratio of frequency domain energy levels 4000/200 Hz during the attack phase of the note for each frame 1-n is the harmonic attack ratio. Other frequency harmonic ratios in the attack phase of the note can be monitored on a frame-by-frame basis. Block 204 determines the rate of change of the energy levels in the harmonic ratio, i.e., how rapidly the energy levels are increasing or decreasing, relative to each frame during the attack phase of the note. The harmonic attack ratio is a frequency domain parameter or characteristic of each frame n and is stored as a value in runtime matrix 174 on a frame-by-frame basis.

Harmonic release ratio block 205 determines a ratio of the energy levels of various frequency harmonics of the frequency domain sampled audio signal 118 during the decay phase or release phase of the note on a frame-by-frame basis. Alternatively, the harmonic release ratio monitors a fundamental frequency and harmonic of the fundamental. In one embodiment, to monitor a slap style, the frequency domain energy level of the sampled audio signal 118 is measured at 200 Hz fundamental of the slap and 4000 Hz harmonic of the fundamental during the release phase of the note. The ratio of frequency domain energy levels 4000/200 Hz during the release phase of the note for each frame 1-n is the harmonic release ratio. Other frequency harmonic ratios in the release phase of the note can be monitored on a frame-by-frame basis. Block 205 determines the rate of change of the energy levels in the harmonic ratio, i.e., how rapidly the energy levels are increasing or decreasing, relative to each frame during the release phase of the note. The harmonic release ratio is a frequency domain parameter or characteristic of each frame n and is stored as a value in runtime matrix 174 on a frame-by-frame basis.

Open and mute factor block 206 monitors the energy levels of the frequency domain sampled audio signal 118 for occurrence of an open state or mute state of strings 24. A mute state of strings 24 occurs when the artist continuously presses his or her fingers against the strings, usually near the bridge of guitar 20. The finger pressure on strings 24 rapidly dampens or attenuates string vibration. An open state is the absence of a mute state, i.e., no finger pressure or other artificial dampening of strings 24 so the string vibration naturally decays. In mute state, the sustain phase and decay phase of the note is significantly shorter due to the induced dampening than a natural decay in the open state. A lack of high frequency content and rapid decrease in the frequency domain energy levels of the sampled audio signal 118 indicates the mute state. A high frequency value and natural decay in the frequency domain energy levels of the sampled audio signal 118 indicates the open state. The open and mute factor is a frequency domain parameter or characteristic of each frame n and is stored as a value in runtime matrix 174 on a frame-by-frame basis.

Neck and bridge factor block 207 monitors the energy levels of the frequency domain sampled audio signal 118 for occurrence of neck play or bridge play by the artist. Neck play of strings 24 occurs when the artist excites the strings near the neck of guitar 20. Bridge play of strings 24 occurs when the artist excites the strings near the bridge of guitar 20. When playing near the neck, a first frequency notch occurs about 100 Hz in the frequency domain response of the sampled audio signal 118. When playing near the bridge, a first frequency notch occurs about 500 Hz in the frequency domain response of the sampled audio signal 118. The occurrence and location of a first notch in the frequency response indicates neck play or bridge play. The neck and bridge factor is a frequency domain parameter or characteristic of each frame n and is stored as a value in runtime matrix 174 on a frame-by-frame basis.

Pitch detector block 208 monitors the energy levels of the frequency domain sampled audio signal 118 to determine the pitch of the note. Block 208 records the fundamental frequency of the pitch. The pitch detector is a frequency domain parameter or characteristic of each frame n and is stored as a value in runtime matrix 174 on a frame-by-frame basis.

Runtime matrix 174 contains the frequency domain parameters determined in frequency domain analysis block 120 and the time domain parameters determined in time domain analysis block 122. Each time domain parameter and frequency domain parameter is a numeric parameter value PVn,j stored in runtime matrix 174 on a frame-by-frame basis, where n is the frame and j is the parameter. For example, the note peak attack parameter has value PV1,1 in frame 1, value PV2,1 in frame 2, and value PVn,1 in frame n; note peak release parameter has value PV1,2 in frame 1, value PV2,2 in frame 2, and value PVn,2 in frame n; multiband peak attack parameter has value PV1,3 in frame 1, value PV2,3 in frame 2, and value PVn,3 in frame n; and so on. Table 1 shows runtime matrix 174 with the time domain and frequency domain parameter values PVn,j generated during the runtime analysis. The time domain and frequency domain parameter values PVn,j are characteristic of specific notes and therefore useful in distinguishing between notes.

TABLE 1
Runtime matrix 174 with time domain parameters and
frequency domain parameters from runtime analysis

| | | | | |
|---|---|---|---|---|
| Parameter | Frame 1 | Frame 2 | . . . | Frame n |

| | | | |
|---|---|---|---|
| Note peak attack | PV1, 1 | PV2, 1 | PVn, 1 |
| Note peak release | PV1, 2 | PV2, 2 | PVn, 2 |
| Multiband peak attack | PV1, 3 | PV2, 3 | PVn, 3 |
| Multiband peak release | PV1, 4 | PV2, 4 | PVn, 4 |
| Slap detector | PV1, 5 | PV2, 5 | PVn, 5 |
| Tempo detector | PV1, 6 | PV2, 6 | PVn, 6 |
| Harmonic attack ratio | PV1, 7 | PV2, 7 | PVn, 7 |
| Harmonic release ratio | PV1, 8 | PV2, 8 | PVn, 8 |
| Open and mute factor | PV1, 9 | PV2, 9 | PVn, 9 |
| Neck and bridge factor | PV1, 10 | PV2, 10 | PVn, 10 |
| Pitch detector | PV1, 11 | PV2, 11 | PVn, 11 |

Table 2 shows one frame of runtime matrix 174 with the time domain and frequency domain parameters generated by frequency domain analysis block 120 and time domain analysis block 122 assigned sample numeric values for an audio signal originating from a fingering style. Runtime matrix 174 contains time domain and frequency domain parameter values PVn,j for other frames of the audio signal originating from the fingering style, as per Table 1.

TABLE 2
Time domain and frequency domain parameters from
runtime analysis of one frame of fingering style

| Parameter | Frame value |
|---|---|
| Note peak attack | 28 |
| Note peak release | 196 |
| Multiband peak attack | 31, 36, 33 |
| Multiband peak release | 193, 177, 122 |
| Slap detector | 0 |
| Tempo detector | 42 |
| Harmonic attack ratio | 0.26 |
| Harmonic release ratio | 0.85 |
| Open and mute factor | 0.19 |
| Neck and bridge factor | 207 |
| Pitch detector | 53 |

Table 3 shows one frame of runtime matrix 174 with the time domain and frequency domain parameters generated by frequency domain analysis block 120 and time domain analysis block 122 assigned sample numeric values for an audio signal originating from a slap style. Runtime matrix 174 contains time domain and frequency domain parameter values PVn,j for other frames of the audio signal originating from the slap style, as per Table 1.

TABLE 3
Time domain parameters and frequency domain parameters
from runtime analysis of one frame of slap style

| Parameter | Frame value |
|---|---|
| Note peak attack | 6 |
| Note peak release | 33 |
| Multiband peak attack | 6, 4, 7 |
| Multiband peak release | 32, 29, 20 |
| Slap detector | 1 |
| Tempo detector | 110 |
| Harmonic attack ratio | 0.90 |
| Harmonic release ratio | 0.24 |
| Open and mute factor | 0.76 |
| Neck and bridge factor | 881 |
| Pitch detector | 479 |

Returning to FIG. 6, database 112 is maintained in a memory component of audio amplifier 90 and contains a plurality of note signature records 1, 2, 3, . . . i, with each note signature record having time domain parameters and frequency domain parameters corresponding to runtime matrix 174. In addition, the note signature records 1-i contain weighting factors 1, 2, 3, . . . j for each time domain and frequency domain parameter, and a plurality of control parameters 1, 2, 3, . . . k.

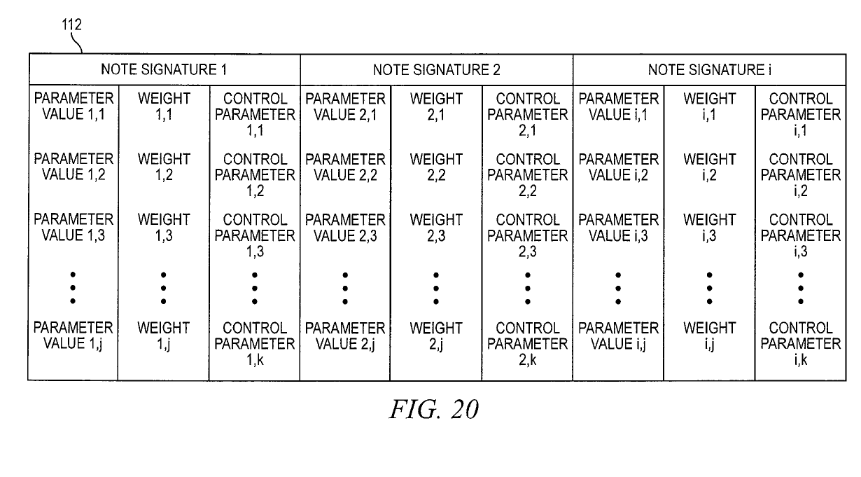

FIG. 20 shows database 112 with time domain and frequency domain parameters 1-j for each note signature record 1-i, weighting factors 1-j for each note signature record 1-i, and control parameters 1-k for each note signature record 1-i. Each note signature record i is defined by the parameters 1-j, and associated weights 1-j, that are characteristic of the note associated with note signature i and will be used to identify an incoming frame from runtime matrix 174 as being best matched or most closely correlated to note signature i. Once the incoming frame from runtime matrix 174 is matched to a particular note signature i, adaptive intelligence control 114 uses the control parameters 1-k of the matching note signature to set the operating state of the signal processing blocks 92-104 of audio amplifier 90. For example, in a matching note signature record i, control parameter i,1 sets the operating state of pre-filter block 92; control parameter i,2 sets the operating state of pre-effects block 94; control parameter i,3 sets the operating state of non-linear effects block 96; control parameter i,4 sets the operating state of user-defined modules 98; control parameter i,5 sets the operating state of post-effects block 100; control parameter i,6 sets the operating state of post-filter block 102; and control parameter i,7 sets the operating state of power amplification block 104.

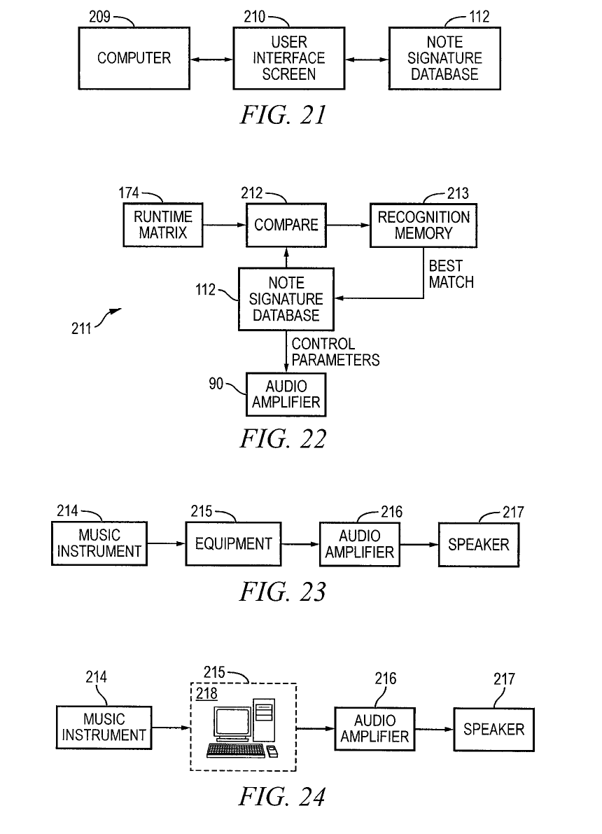

The time domain parameters and frequency domain parameters 1-j in note signature database 112 contain values preset by the manufacturer, or entered by the user, or learned over time by playing an instrument. The factory or manufacturer of audio amplifier 90 can initially preset the values of time domain and frequency domain parameters 1-j, as well as weighting factors 1-j and control parameters 1-k. The user can change time domain and frequency domain parameters 1-j, weighting factors 1-j, and control parameters 1-k for each note signature 1-i in database 112 directly using computer 209 with user interface screen or display 210, see FIG. 21. The values for time domain and frequency domain parameters 1-j, weighting factors 1-j, and control parameters 1-k are presented with interface screen 210 to allow the user to enter updated values.

In another embodiment, time domain and frequency domain parameters 1-j, weighting factors 1-j, and control parameters 1-k can be learned by the artist playing guitar 20. The artist sets audio amplifier 90 to a learn mode. The artist repetitively plays the same note on guitar 20. For example, the artist fingers a particular note or slaps of a particular note many times in repetition. The frequency domain analysis 120 and time domain analysis 122 of FIG. 8 creates a runtime matrix 174 with associated frequency domain and time domain parameters 1-j each time the same note is played. A series of frequency domain and time domain parameters 1-j for the same note is accumulated and stored in database 112.

As the note is played in repetition, the artist can make manual adjustments to audio amplifier 90 via front control panel 78. Audio amplifier 90 learns control parameters 1-k associated with the note by the settings of the signal processing blocks 92-104 as manually set by the artist. For example, the artist slaps a note on bass guitar 20. Frequency domain parameters and time domain parameters for the slap note are stored frame-by-frame in database 112. The artist manually adjusts the signal processing blocks 92-104 of audio amplifier 90 through front panel controls 78, e.g., increases the amplification of the audio signal in amplification block 104 or selects a sound effect in pre-effects block 94. The settings of signal processing blocks 92-104, as manually set by the artist, are stored as control parameters 1-k for the note signature being learned in database 112. The artist slaps the same note on bass guitar 20. Frequency domain parameters and time domain parameters for the same slap note are accumulated with the previous frequency domain and time domain parameters 1-j in database 112. The artist manually adjusts the signal processing blocks 92-104 of audio amplifier 90 through front panel controls 78, e.g., adjust equalization of the audio signal in pre-filter block 92 or selects a sound effect in non-linear effects block 96. The settings of signal processing blocks 92-104, as manually set by the artist, are accumulated as control parameters 1-k for the note signature being learned in database 112. The process continues for learn mode with repetitive slaps of the same note and manual adjustments of the signal processing blocks 92-104 of audio amplifier 90 through front panel controls 78. When learn mode is complete, the note signature record in database 112 is defined with the note signature parameters being an average of the frequency domain parameters and time domain parameters accumulated in database 112, and an average of the control parameters 1-k taken from the manual adjustments of the signal processing blocks 92-104 of audio amplifier 90 and accumulated in database 112. In one embodiment, the average is a root mean square of the series of accumulated frequency domain and time domain parameters 1-j and accumulated control parameters 1-k in database 112.

Weighting factors 1-j can be learned by monitoring the learned time domain and frequency domain parameters 1-j and increasing or decreasing the weighting factors based on the closeness or statistical correlation of the comparison. If a particular parameter exhibits a consistent statistical correlation, then the weighting factor for that parameter can be increased. If a particular parameter exhibits a diverse statistical correlation, then the weighting factor for that parameter can be decreased.

Once the parameters 1-j, weighting factors 1-j, and control parameters 1-k of note signatures 1-i are established for database 112, the time domain and frequency domain parameters 1-j in runtime matrix 174 can be compared on a frame-by-frame basis to each note signature 1-i to find a best match or closest correlation. In normal play mode, the artist plays guitar 20 to generate a sequence of notes corresponding to the melody being played. For each note, runtime matrix 174 is populated on a frame-by-frame basis with time domain parameters and frequency domain parameters determined from a runtime analysis of the audio signal, as described in FIGS. 6-19.

The comparison between runtime matrix 174 and note signatures 1-i in database 112 can be made in a variety of implementations. For example, the time domain and frequency domain parameters 1-j in runtime matrix 714 are compared one-by-one in time sequence to parameters 1-j for each note signature 1-i in database 112. The best match or closest correlation is determined for each frame of runtime matrix 174. Adaptive intelligence control block 114 uses the control parameters 1-k in database 112 associated with the matching note signature to control operation of the signal processing blocks 92-104 of audio amplifier 90.

In another example, the time domain and frequency domain parameters 1-j in a predetermined number of the frames of a note, less than all the frames of a note, in runtime matrix 174 are compared to parameters 1-j for each note signature 1-i in database 112. In one embodiment, the time domain and frequency domain parameters 1-j in the first ten frames of each note in runtime matrix 174, as determined by the onset detection of the note, are compared to parameters 1-j for each note signature 1-i. An average of the comparisons between time domain and frequency domain parameters 1-j in each of the first ten frames of each note in runtime matrix 174 and parameters 1-j for each note signature 1-i will determine a best match or closest correlation to identify the frames in runtime matrix 174 as being a particular note associated with a note signature i. Adaptive intelligence control block 114 uses the control parameters 1-k in database 112 associated with the matching note signature to control operation of the signal processing blocks 92-104 of audio amplifier 90.

In a illustrative numeric example of the parameter comparison process to determine a best match or closest correlation between the time domain and frequency domain parameters 1-j for each frame in runtime matrix 174 and parameters 1-j for each note signature 1-i, Table 4 shows time domain and frequency domain parameters 1-j with sample parameter values for note signature 1 (fingering style note) of database 112. Table 5 shows time domain and frequency domain parameters 1-j with sample parameter values for note signature 2 (slap style note) of database 112.

TABLE 4
Time domain parameters and frequency domain parameters
for note signature 1 (fingering style)

| Parameter | Value | Weighting |
|---|---|---|
| Note peak attack | 30 | 0.83 |
| Note peak release | 200 | 0.67 |
| Multiband peak attack | 30, 35, 33 | 0.72 |
| Multiband peak release | 200, 180, 120 | 0.45 |
| Slap detector | 0 | 1.00 |
| Tempo detector | 50 | 0.38 |
| Harmonic attack ratio | 0.25 | 0.88 |
| Harmonic release ratio | 0.80 | 0.61 |
| Open and mute factor | 0.15 | 0.70 |
| Neck and bridge factor | 200 | 0.69 |
| Pitch detector | 50 | 0.40 |

TABLE 5
Time domain parameters and frequency domain
parameters in note signature 2 (slap style)

| Parameter | Value | Weighting |
|---|---|---|
| Note peak attack | 5 | 0.80 |
| Note peak release | 40 | 0.71 |
| Multiband peak attack | 5, 4, 5 | 0.65 |
| Multiband peak release | 30, 25, 23 | 0.35 |
| Slap detector | 1 | 1.00 |
| Tempo detector | 100 | 0.27 |
| Harmonic attack ratio | 0.85 | 0.92 |
| Harmonic release ratio | 0.20 | 0.69 |
| Open and mute factor | 0.65 | 0.74 |
| Neck and bridge factor | 1000 | 0.80 |
| Pitch detector | 500 | 0.57 |

The time domain and frequency domain parameters 1-j for one frame in runtime matrix 174 and the parameters 1-j in each note signatures 1-i are compared on a one-by-one basis and the differences are recorded. For example, the note peak attack parameter of frame 1 in runtime matrix 174 has a value of 28 (see Table 2) and the note peak attack parameter in note signature 1 has a value of 30 (see Table 4). FIG. 22 shows a recognition detector 211 with compare block 212 for determining the difference between time domain and frequency domain parameters 1-j for one frame in runtime matrix 174 and the parameters 1-j in note signature i. The difference 30−28 between frame 1 and note signature 1 is stored in recognition memory 213. The note peak release parameter of frame 1 in runtime matrix 174 has a value of 196 (see Table 2) and the note peak release parameter in note signature 1 has a value of 200 (see Table 4). Compare block 212 determines the difference 200−196 and stores the difference in recognition memory 213. For each parameter of frame 1, compare block 212 determines the difference between the parameter value in runtime matrix 174 and the parameter value in note signature 1 and stores the difference in recognition memory 213. The differences between the parameters 1-j of frame 1 and the parameters 1-j of note signature 1 are summed to determine a total difference value between the parameters 1-j of frame 1 and the parameters 1-j of note signature 1.

Next, the note peak attack parameter of frame 1 in runtime matrix 174 has a value of 28 (see Table 2) and the note peak attack parameter in note signature 2 has a value of 5 (see Table 5). Compare block 212 determines the difference 5−28 and stores the difference between frame 1 and note signature 2 in recognition memory 213. The note peak release parameter of frame 1 in runtime matrix 174 has a value of 196 (see Table 2) and the note peak release parameter in note signature 2 has a value of 40 (see Table 5). Compare block 212 determines the difference 40−196 and stores the difference in recognition memory 213. For each parameter of frame 1, compare block 212 determines the difference between the parameter value in runtime matrix 174 and the parameter value in note signature 2 and stores the difference in recognition memory 213. The differences between the parameters 1-j in runtime matrix 174 for frame 1 and the parameters 1-j of note signature 2 are summed to determine a total difference value between the parameters 1-j in runtime matrix 174 for frame 1 and the parameters 1-j of note signature 2.

The time domain and frequency domain parameters 1-j in runtime matrix 174 for frame 1 are compared to the time domain and frequency domain parameters 1-j in the remaining note signatures 3-i in database 112, as described for note signatures 1 and 2. The minimum total difference between the parameters 1-j in runtime matrix 174 for frame 1 and the parameters 1-j of note signatures 1-i is the best match or closest correlation. In this case, the time domain and frequency domain parameters 1-j in runtime matrix 174 for frame 1 are more closely aligned to the time domain and frequency domain parameters 1-j in note signature 1. Frame 1 of runtime matrix 174 is identified as a frame of a fingering style note.

With time domain parameters and frequency domain parameters 1-j of frame 1 in runtime matrix 174 generated from a played note matched to note signature 1, adaptive intelligence control block 114 of FIG. 6 uses the control parameters 1-k in database 112 associated with the matching note signature 1 to control operation of the signal processing blocks 92-104 of audio amplifier 90. The control parameter 1,1, control parameter 1,2, through control parameter 1,k under note signature 1 each have a numeric value, e.g., 1-10. For example, control parameter 1,1 has a value 5 and sets the operating state of pre-filter block 92 to have a low-pass filter function at 200 Hz; control parameter 1,2 has a value 7 and sets the operating state of pre-effects block 94 to engage a reverb sound effect; control parameter 1,3 has a value 9 and sets the operating state of non-linear effects block 96 to introduce distortion; control parameter 1,4 has a value 1 and sets the operating state of user-defined modules 98 to add a drum accompaniment; control parameter 1,5 has a value 3 and sets the operating state of post-effects block 100 to engage a hum canceller sound effect; control parameter 1,6 has a value 4 and sets the operating state of post-filter block 102 to enable bell equalization; and control parameter 1,7 has a value 8 and sets the operating state of power amplification block 104 to increase amplification by 3 dB. The audio signal is processed through pre-filter block 92, pre-effects block 94, non-linear effects block 96, user-defined modules 98, post-effects block 100, post-filter block 102, and power amplification block 104, each operating as set by control parameter 1,1, control parameter 1,2, through control parameter 1,k of note signature 1. The enhanced audio signal is routed to the speaker in enclosure 24 or speaker 82 in enclosure 72. The listener hears the reproduced audio signal enhanced in realtime with characteristics determined by the dynamic content of the audio signal.

Next, the time domain and frequency domain parameters 1-j for frame 2 in runtime matrix 174 and the parameters 1-j in each note signatures 1-i are compared on a one-by-one basis and the differences are recorded. For each parameter 1-j of frame 2, compare block 212 determines the difference between the parameter value in runtime matrix 174 and the parameter value in note signature i and stores the difference in recognition memory 213. The differences between the parameters 1-j of frame 2 and the parameters 1-j of note signature i are summed to determine a total difference value between the parameters 1-j of frame 2 and the parameters 1-j of note signature i. The minimum total difference between the parameters 1-j of frame 2 of runtime matrix 174 and the parameters 1-j of note signatures 1-i is the best match or closest correlation. Frame 2 of runtime matrix 174 is identified with the note signature having the minimum total difference between corresponding parameters. In this case, the time domain and frequency domain parameters 1-j of frame 2 in runtime matrix 174 are more closely aligned to the time domain and frequency domain parameters 1-j in note signature 1. Frame 2 of runtime matrix 174 is identified as another frame for a fingering style note. Adaptive intelligence control block 114 uses the control parameters 1-k in database 112 associated with the matching note signature 1 to control operation of the signal processing blocks 92-104 of audio amplifier 90. The process continues for each frame n of runtime matrix 174.

In another numeric example, the note peak attack parameter of frame 1 in runtime matrix 174 has a value of 6 (see Table 3) and the note peak attack parameter in note signature 1 has a value of 30 (see Table 4). The difference 30−6 between frame 1 and note signature 1 is stored in recognition memory 213. The note peak release parameter of frame 1 in runtime matrix 174 has a value of 33 (see Table 3) and the note peak release parameter in note signature 1 has a value of 200 (see Table 4). Compare block 212 determines the difference 200−33 and stores the difference in recognition memory 213. For each parameter of frame 1, compare block 212 determines the difference between the parameter value in runtime matrix 174 and the parameter value in note signature 1 and stores the difference in recognition memory 213. The differences between the parameters 1-j of frame 1 in runtime matrix 174 and the parameters 1-j of note signature 1 are summed to determine a total difference value between the parameters 1-j of frame 1 and the parameters 1-j of note signature 1.

Next, the note peak attack parameter of frame 1 in runtime matrix 174 has a value of 6 (see Table 3) and the note peak attack parameter in note signature 2 has a value of 5 (see Table 5). Compare block 212 determines the difference 5−6 and stores the difference in recognition memory 213. The note peak release parameter of frame 1 in runtime matrix 174 has a value of 33 (see Table 3) and the note peak release parameter in note signature 2 has a value of 40 (see Table 5). Compare block 212 determines the difference 40−33 and stores the difference in recognition memory 213. For each parameter of frame 1, compare block 212 determines the difference between the parameter value in runtime matrix 174 and the parameter value in note signature 2 and stores the difference in recognition memory 213. The differences between the parameters 1-j of frame 1 and the parameters 1-j of note signature 2 are summed to determine a total difference value between the parameters 1-j of frame 1 and the parameters 1-j of note signature 2.

The time domain and frequency domain parameters 1-j in runtime matrix 174 for frame 1 are compared to the time domain and frequency domain parameters 1-j in the remaining note signatures 3-i in database 112, as described for note signatures 1 and 2. The minimum total difference between the parameters 1-j of frame 1 of runtime matrix 174 and the parameters 1-j of note signatures 1-i is the best match or closest correlation. Frame 1 of runtime matrix 174 is identified with the note signature having the minimum total difference between corresponding parameters. In this case, the time domain and frequency domain parameters 1-j of frame 1 in runtime matrix 174 are more closely aligned to the time domain and frequency domain parameters 1-j in note signature 2. Frame 1 of runtime matrix 174 is identified as a frame of a slap style note.

With time domain parameters and frequency domain parameters 1-j of frame 1 in runtime matrix 174 generated from a played note matched to note signature 2, adaptive intelligence control block 114 of FIG. 6 uses the control parameters 1-k in database 112 associated with the matching note signature 2 to control operation of the signal processing blocks 92-104 of audio amplifier 90. The audio signal is processed through pre-filter block 92, pre-effects block 94, non-linear effects block 96, user-defined modules 98, post-effects block 100, post-filter block 102, and power amplification block 104, each operating as set by control parameter 2,1, control parameter 2,2, through control parameter 2,k of note signature 2. The enhanced audio signal is routed to the speaker in enclosure 24 or speaker 82 in enclosure 72. The listener hears the reproduced audio signal enhanced in realtime with characteristics determined by the dynamic content of the audio signal.

The time domain and frequency domain parameters 1-j for frame 2 in runtime matrix 174 and the parameters 1-j in each note signatures 1-i are compared on a one-by-one basis and the differences are recorded. For each parameter 1-j of frame 2, compare block 212 determines the difference between the parameter value in runtime matrix 174 and the parameter value in note signature i and stores the difference in recognition memory 213. The differences between the parameters 1-j of frame 2 and the parameters 1-j of note signature i are summed to determine a total difference value between the parameters 1-j of frame 2 and the parameters 1-j of note signature i. The minimum total difference between the parameters 1-j of frame 2 of runtime matrix 174 and the parameters 1-j of note signatures 1-i is the best match or closest correlation. Frame 2 of runtime matrix 174 is identified with the note signature having the minimum total difference between corresponding parameters. In this case, the time domain and frequency domain parameters 1-j of frame 2 in runtime matrix 174 are more closely aligned to the time domain and frequency domain parameters 1-j in note signature 2. Frame 2 of runtime matrix 174 is identified as another frame of a slap style note. Adaptive intelligence control block 114 uses the control parameters 1-k in database 112 associated with the matching note signature 2 to control operation of the signal processing blocks 92-104 of audio amplifier 90. The process continues for each frame n of runtime matrix 174.

In another embodiment, the time domain and frequency domain parameters 1-j for one frame in runtime matrix 174 and the parameters 1-j in each note signatures 1-i are compared on a one-by-one basis and the weighted differences are recorded. For example, the note peak attack parameter of frame 1 in runtime matrix 174 has a value of 28 (see Table 2) and the note peak attack parameter in note signature 1 has a value of 30 (see Table 4). Compare block 212 determines the weighted difference (30−28)*weight 1,1 and stores the weighted difference in recognition memory 213. The note peak release parameter of frame 1 in runtime matrix 174 has a value of 196 (see Table 2) and the note peak release parameter in note signature 1 has a value of 200 (see Table 4). Compare block 212 determines the weighted difference (200−196)*weight 1,2 and stores the weighted difference in recognition memory 213. For each parameter of frame 1, compare block 212 determines the weighted difference between the parameter value in runtime matrix 174 and the parameter value in note signature 1 as determined by weight 1,j and stores the weighted difference in recognition memory 213. The weighted differences between the parameters 1-j of frame 1 and the parameters 1-j of note signature 1 are summed to determine a total weighted difference value between the parameters 1-j of frame 1 and the parameters 1-j of note signature 1.

Next, the note peak attack parameter of frame 1 in runtime matrix 174 has a value of 28 (see Table 2) and the note peak attack parameter in note signature 2 has a value of 5 (see Table 5). Compare block 212 determines the weighted difference (5−28)*weight 2,1 and stores the weighted difference in recognition memory 213. The note peak release parameter of frame 1 in runtime matrix 174 has a value of 196 (see Table 2) and the note peak release parameter in note signature 2 has a value of 40 (see Table 5). Compare block 212 determines the weighted difference (40−196)*weight 2,2 and stores the weighted difference in recognition memory 213. For each parameter of frame 1, compare block 212 determines the weighted difference between the parameter value in runtime matrix 174 and the parameter value in note signature 2 by weight 2,j and stores the weighted difference in recognition memory 213. The weighted differences between the parameters 1-j of frame 1 in runtime matrix 174 and the parameters 1-j of note signature 2 are summed to determine a total weighted difference value between the parameters 1-j of frame 1 and the parameters 1-j of note signature 2.

The time domain and frequency domain parameters 1-j in runtime matrix 174 for frame 1 are compared to the time domain and frequency domain parameters 1-j in the remaining note signatures 3-i in database 112, as described for note signatures 1 and 2. The minimum total weighted difference between the parameters 1-j of frame 1 of runtime matrix 174 and the parameters 1-j of note signatures 1-i is the best match or closest correlation. Frame 1 of runtime matrix 174 is identified with the note signature having the minimum total weighted difference between corresponding parameters. Adaptive intelligence control block 114 uses the control parameters 1-k in database 112 associated with the matching note signature to control operation of the signal processing blocks 92-104 of audio amplifier 90.

The time domain and frequency domain parameters 1-j for frame 2 in runtime matrix 174 and the parameters 1-j in each note signatures 1-i are compared on a one-by-one basis and the weighted differences are recorded. For each parameter 1-j of frame 2, compare block 212 determines the weighted difference between the parameter value in runtime matrix 174 and the parameter value in note signature i by weight i,j and stores the weighted difference in recognition memory 213. The weighted differences between the parameters 1-j of frame 2 and the parameters 1-j of note signature i are summed to determine a total weighted difference value between the parameters 1-j of frame 2 and the parameters 1-j of note signature i. The minimum total weighted difference between the parameters 1-j of frame 2 of runtime matrix 174 and the parameters 1-j of note signatures 1-i is the best match or closest correlation. Frame 2 of runtime matrix 174 is identified with the note signature having the minimum total weighted difference between corresponding parameters. Adaptive intelligence control block 114 uses the control parameters 1-k in database 112 associated with the matching note signature to control operation of the signal processing blocks 92-104 of audio amplifier 90. The process continues for each frame n of runtime matrix 174.

In another embodiment, a probability of correlation between corresponding parameters in runtime matrix 174 and note signatures 1-i is determined. In other words, a probability of correlation is determined as a percentage that a given parameter in runtime matrix 174 is likely the same as the corresponding parameter in note signature i. The percentage is a likelihood of a match. As described above, the time domain parameters and frequency domain parameters in runtime matrix 174 are stored on a frame-by-frame basis. For each frame n of each parameter j in runtime matrix 174 is represented by Pn,j=[Pn1, Pn2, . . . Pnj].

A probability ranked list R is determined between each frame n of each parameter j in runtime matrix 174 and each parameter j of each note signature i. The probability value rᵢ can be determined by a root mean square analysis for the Pn,j and note signature database Si,j in equation (3):

$${r}_{i} = \sqrt{\frac{{( {P}_{n 1} - {S}_{i 1} )}^{2} + {( {P}_{n 2} - {S}_{i 2} )}^{2} + … {( {P}_{nj} - {S}_{ij} )}^{2}}{j}} \qquad ( 3 )$$

The probability value R is (1−rᵢ)×100%. The overall ranking value for Pn,j and note database S_{i,j} is given in equation (4).

R=[(1−r₁)×100%(1−r₂)×100%(1−rᵢ)×100%] (4)

In some cases, the matching process identifies two or more note signatures that are close to the played note. For example, the played note may have a 52% probability that it matches to note signature 1 and a 48% probability that it matches to note signature 2. In this case, an interpolation is performed between the control parameter 1,1, control parameter 1,2, through control parameter 1,k, and control parameter 2,1, control parameter 2,2, through control parameter 2,k, weighted by the probability of the match. The net effective control parameter 1 is 0.52*control parameter 1,1+0.48*control parameter 2,1. The net effective control parameter 2 is 0.52*control parameter 1,2+0.48*control parameter 2,2. The net effective control parameter k is 0.52*control parameter 1,k+0.48*control parameter 2,k. The net effective control parameters 1-k control operation of the signal processing blocks 92-104 of audio amplifier 90. The audio signal is processed through pre-filter block 92, pre-effects block 94, non-linear effects block 96, user-defined modules 98, post-effects block 100, post-filter block 102, and power amplification block 104, each operating as set by net effective control parameters 1-k. The audio signal is routed to the speaker in enclosure 24 or speaker 82 in enclosure 72. The listener hears the reproduced audio signal enhanced in realtime with characteristics determined by the dynamic content of the audio signal.

The adaptive intelligence control described in FIGS. 6-22 is applicable to other musical instruments that generate notes having a distinct attack phase, followed by a sustain phase, decay phase, and release phase. For example, the audio signal can originate from a string musical instrument, such as a violin, fiddle, harp, mandolin, viola, banjo, cello, just to name a few. The audio signal can originate from percussion instruments, such as drums, bells, chimes, cymbals, piano, tambourine, xylophone, and the like. The audio signal is processed through time domain analysis block 122 and frequency domain analysis block 120 on a frame-by-frame basis to isolate the note being played and determine its characteristics. Each time domain and frequency domain analyzed frame is compared to note signatures 1-i in database 112 to identify the type of note and determine the appropriate control parameters 1-k. The signal processing functions in audio amplifier 90 are set according to the control parameters 1-k of the matching note signature to reproduce audio signal in realtime with enhanced characteristics determined by the dynamic content of the audio signal.

The signal processing functions can be associated with equipment other than a dedicated audio amplifier. FIG. 23 shows musical instrument 214 generating an audio signal routed to equipment 215. The equipment 215 performs the signal processing functions on the audio signal. The signal conditioned audio signal is routed to audio amplifier 216 for power amplification or attenuation of the audio signal. The audio signal is then routed to speaker 217 to reproduce the sound content of musical instrument 214 with the enhancements introduced into the audio signal by signal processing equipment 215.

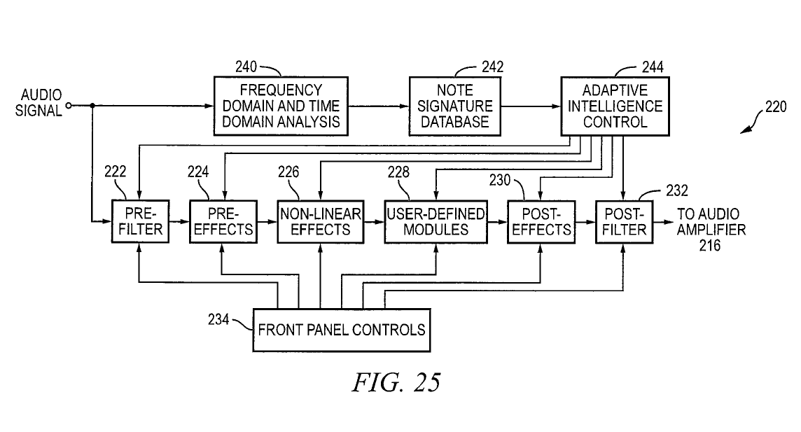

In one embodiment, signal processing equipment 215 is a computer 218, as shown in FIG. 24. Computer 218 contains digital signal processing components and software to implement the signal processing function. FIG. 25 is a block diagram of signal processing function 220 contained within computer 218, including pre-filter block 222, pre-effects block 224, non-linear effects block 226, user-defined modules 228, post-effects block 230, and post-filter block 232. Pre-filtering block 222 and post-filtering block 232 provide various filtering functions, such as low-pass filtering and bandpass filtering of the audio signal. The pre-filtering and post-filtering can include tone equalization functions over various frequency ranges to boost or attenuate the levels of specific frequencies without affecting neighboring frequencies, such as bass frequency adjustment and treble frequency adjustment. For example, the tone equalization may employ shelving equalization to boost or attenuate all frequencies above or below a target or fundamental frequency, bell equalization to boost or attenuate a narrow range of frequencies around a target or fundamental frequency, graphic equalization, or parametric equalization. Pre-effects block 224 and post-effects block 230 introduce sound effects into the audio signal, such as reverb, delays, chorus, wah, auto-volume, phase shifter, hum canceller, noise gate, vibrato, pitch-shifting, graphic equalization, tremolo, and dynamic compression. Non-linear effects block 226 introduces non-linear effects into the audio signal, such as m-modeling, distortion, overdrive, fuzz, and modulation. User-defined module block 228 allows the user to define customized signal processing functions, such as adding accompanying instruments, vocals, and synthesizer options. The post signal processing audio signal is routed to audio amplifier 216 and speaker 217.

The pre-filter block 222, pre-effects block 224, non-linear effects block 226, user-defined modules 228, post-effects block 230, and post-filter block 232 within the signal processing function are selectable and controllable with front control panel 234, i.e., by the computer keyboard or external control signal to computer 218.

To accommodate the signal processing requirements for the dynamic content of the audio source, computer 218 employs a dynamic adaptive intelligence feature involving frequency domain analysis and time domain analysis of the audio signal on a frame-by-frame basis and automatically and adaptively controls operation of the signal processing functions and settings within the computer to achieve an optimal sound reproduction. The audio signal from musical instrument 214 is routed to frequency domain and time domain analysis block 240. The output of block 240 is routed to note signature block 242, and the output of block 242 is routed to adaptive intelligence control block 244.

The functions of blocks 240, 242, and 244 correspond to blocks 110, 112, and 114, respectively, as described in FIGS. 6-19. Blocks 240-244 perform realtime frequency domain analysis and time domain analysis of the audio signal on a frame-by-frame basis. Each incoming frame of the audio signal is detected and analyzed to determine its time domain and frequency domain content and characteristics. The incoming frame is compared to a database of established or learned note signatures to determine a best match or closest correlation of the incoming frame to the database of note signatures. The best matching note signature from the database contains the control configuration of signal processing blocks 222-232. The best matching note signature controls operation of signal processing blocks 222-232 in realtime on a frame-by-frame basis to continuously and automatically make adjustments to the signal processing functions for an optimal sound reproduction, as described in FIGS. 6-19. For example, based on the control parameters 1-k of the matching note signature, the amplification of the audio signal can be increased or decreased automatically for that particular note. Presets and sound effects can be engaged or removed automatically for the note being played. The next frame in sequence may be associated with the same note which matches with the same note signature in the database, or the next frame in sequence may be associated with a different note which matches with a different corresponding note signature in the database. Each frame is recognized and matched to a note signature that contains control parameters 1-k to control operation of the signal processing blocks 222-232 within audio amplifier 220 for optimal sound reproduction. The signal processing blocks 222-232 are adjusted in accordance with the best matching note signature corresponding to each individual incoming frame to enhance its reproduction.

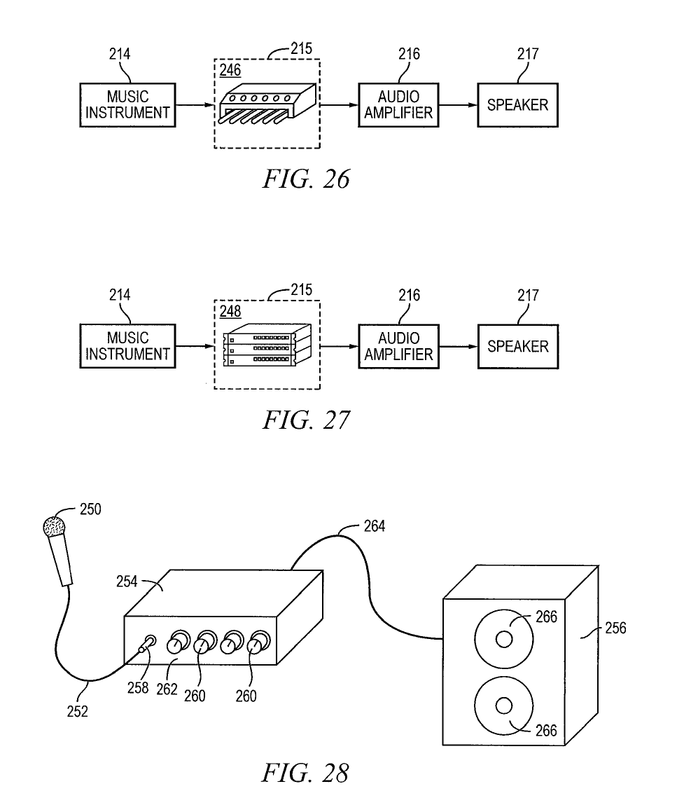

FIG. 26 shows another embodiment of signal processing equipment 215 as pedal board or tone engine 246. Pedal board 246 contains signal processing blocks, as described for FIG. 25 and referenced to FIGS. 6-22. Pedal board 246 employs a dynamic adaptive intelligence feature involving frequency domain analysis and time domain analysis of the audio signal on a frame-by-frame basis and automatically and adaptively controls operation of the signal processing functions and settings within the pedal board to achieve an optimal sound reproduction. Each incoming frame of the audio signal is detected and analyzed to determine its time domain and frequency domain content and characteristics. The incoming frame is compared to a database of established or learned note signatures to determine a best match or closest correlation of the incoming frame to the database of note signatures. The best matching note signature contains control parameters 1-k that control operation of the signal processing blocks in realtime on a frame-by-frame basis to continuously and automatically make adjustments to the signal processing functions for an optimal sound reproduction.

FIG. 27 shows another embodiment of signal processing equipment 215 as signal processing rack 248. Signal processing rack 248 contains signal processing blocks, as described for FIG. 25 and referenced to FIGS. 6-22. Signal processing rack 248 employs a dynamic adaptive intelligence feature involving frequency domain analysis and time domain analysis of the audio signal on a frame-by-frame basis and automatically and adaptively controls operation of the signal processing functions and settings within the signal processing rack to achieve an optimal sound reproduction. Each incoming frame of the audio signal is detected and analyzed to determine its time domain and frequency domain content and characteristics. The incoming frame is compared to a database of established or learned note signatures to determine a best match or closest correlation of the incoming frame to the database of note signatures. The best matching note signature contains control parameters 1-k that control operation of the signal processing blocks in realtime on a frame-by-frame basis to continuously and automatically make adjustments to the signal processing functions for an optimal sound reproduction.

Some embodiments of audio source 12 are better characterized on a frame-by-frame basis, i.e., no clear or reliably detectable delineation between notes. For example, the audio signal from vocal patterns may be better suited to a frame-by-frame analysis without detecting the onset of a note. FIG. 28 shows audio source 12 represented as microphone 250 which is handled by a male or female with voice ranges including soprano, mezzo-soprano, contralto, tenor, baritone, and bass. Microphone 250 is connected by audio cable 252 to an audio system including an audio amplifier contained within a first enclosure 254 and a speaker housed within a second separate enclosure 256. Audio cable 252 from microphone 250 is routed to audio input jack 258, which is connected to the audio amplifier within enclosure 254 for power amplification and signal processing. Control knobs 260 on front control panel 262 of enclosure 254 allow the user to monitor and manually control various settings of the audio amplifier. Enclosure 254 is electrically connected by audio cable 264 to enclosure 256 to route the amplified and conditioned audio signal to speakers 266.

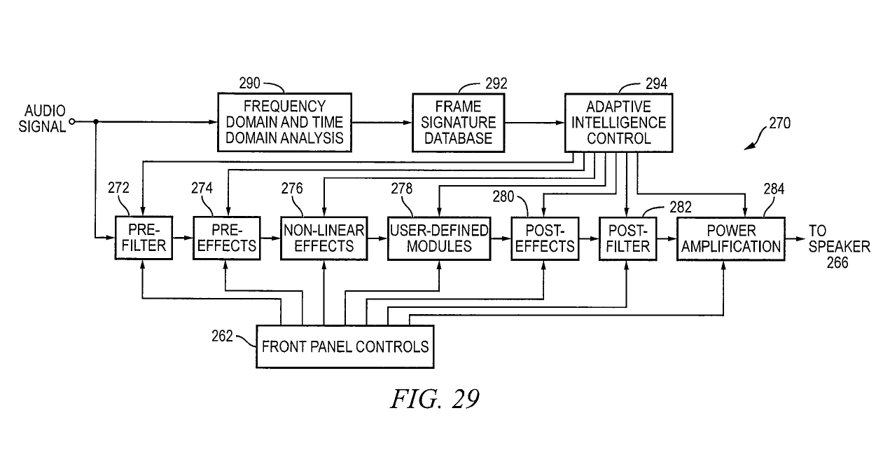

FIG. 29 is a block diagram of audio amplifier 270 contained within enclosure 254. Audio amplifier 270 receives audio signals from microphone 250 by way of audio cable 252. Audio amplifier 270 performs amplification and other signal processing functions, such as equalization, filtering, sound effects, and user-defined modules, on the audio signal to adjust the power level and otherwise enhance the signal properties for the listening experience.

Audio amplifier 270 has a signal processing path for the audio signal, including pre-filter block 272, pre-effects block 274, non-linear effects block 276, user-defined modules 278, post-effects block 280, post-filter block 282, and power amplification block 284. Pre-filtering block 272 and post-filtering block 282 provide various filtering functions, such as low-pass filtering and bandpass filtering of the audio signal. The pre-filtering and post-filtering can include tone equalization functions over various frequency ranges to boost or attenuate the levels of specific frequencies without affecting neighboring frequencies, such as bass frequency adjustment and treble frequency adjustment. For example, the tone equalization may employ shelving equalization to boost or attenuate all frequencies above or below a target or fundamental frequency, bell equalization to boost or attenuate a narrow range of frequencies around a target or fundamental frequency, graphic equalization, or parametric equalization. Pre-effects block 274 and post-effects block 280 introduce sound effects into the audio signal, such as reverb, delays, chorus, wah, auto-volume, phase shifter, hum canceller, noise gate, vibrato, pitch-shifting, graphic equalization, tremolo, and dynamic compression. Non-linear effects block 276 introduces non-linear effects into the audio signal, such as m-modeling, distortion, overdrive, fuzz, and modulation. User-defined module block 278 allows the user to define customized signal processing functions, such as adding accompanying instruments, vocals, and synthesizer options. Power amplification block 284 provides power amplification or attenuation of the audio signal. The post signal processing audio signal is routed to speakers 266 in enclosure 256.

The pre-filter block 272, pre-effects block 274, non-linear effects block 276, user-defined modules 278, post-effects block 280, post-filter block 282, and power amplification block 284 within audio amplifier 270 are selectable and controllable with front control panel 262. By turning knobs 260 on front control panel 262, the user can directly control operation of the signal processing functions within audio amplifier 270.

FIG. 29 further illustrates the dynamic adaptive intelligence control of audio amplifier 270. A primary purpose of the adaptive intelligence feature of audio amplifier 270 is to detect and isolate the frequency domain characteristics and time domain characteristics of the audio signal on a frame-by-frame basis and use that information to control operation of the signal processing blocks 272-284 of the amplifier. The audio signal from audio cable 252 is routed to frequency domain and time domain analysis block 290. The output of block 290 is routed to frame signature block 292, and the output of block 292 is routed to adaptive intelligence control block 294. The functions of blocks 290, 292, and 294 are discussed in sequence.

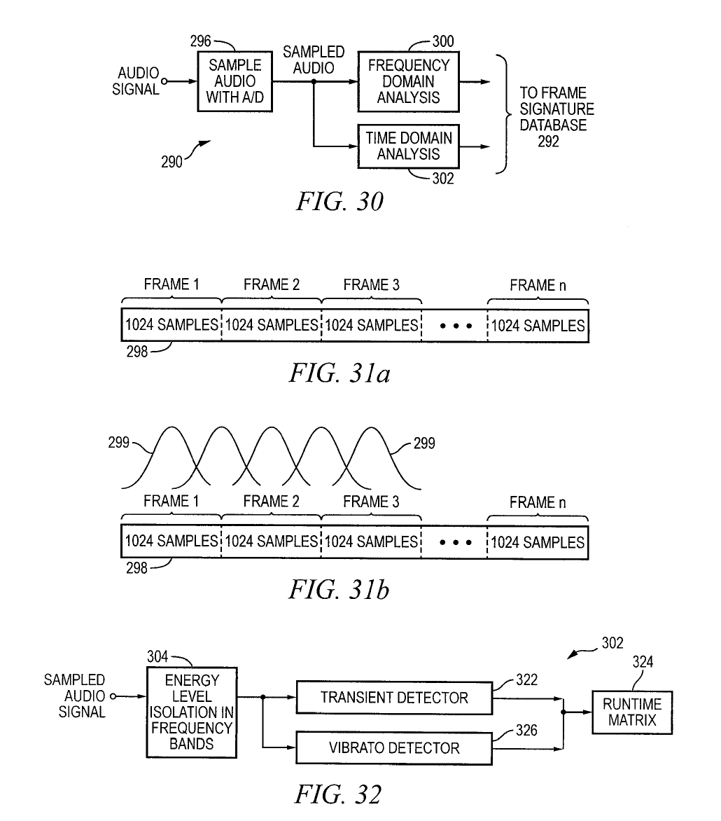

FIG. 30 illustrates further detail of frequency domain and time domain analysis block 290, including sample audio block 296, frequency domain analysis block 300, and time domain analysis block 302. The analog audio signal is presented to sample audio block 296. The sampled audio block 296 samples the analog audio signal, e.g., 512 to 1024 samples per second, using an A/D converter. The sampled audio signal 298 is organized into a series of time progressive frames (frame 1 to frame n) each containing a predetermined number of samples of the audio signal. FIG. 31a shows frame 1 containing 1024 samples of the audio signal 298 in time sequence, frame 2 containing the next 1024 samples of the audio signal 298 in time sequence, frame 3 containing the next 1024 samples of the audio signal 298 in time sequence, and so on through frame n containing 1024 samples of the audio signal 298 in time sequence. FIG. 31b shows overlapping windows 299 of frames 1-n used in time domain to frequency domain conversion, as described in FIG. 34. The sampled audio signal 298 is routed to frequency domain analysis block 300 and time domain analysis block 302.

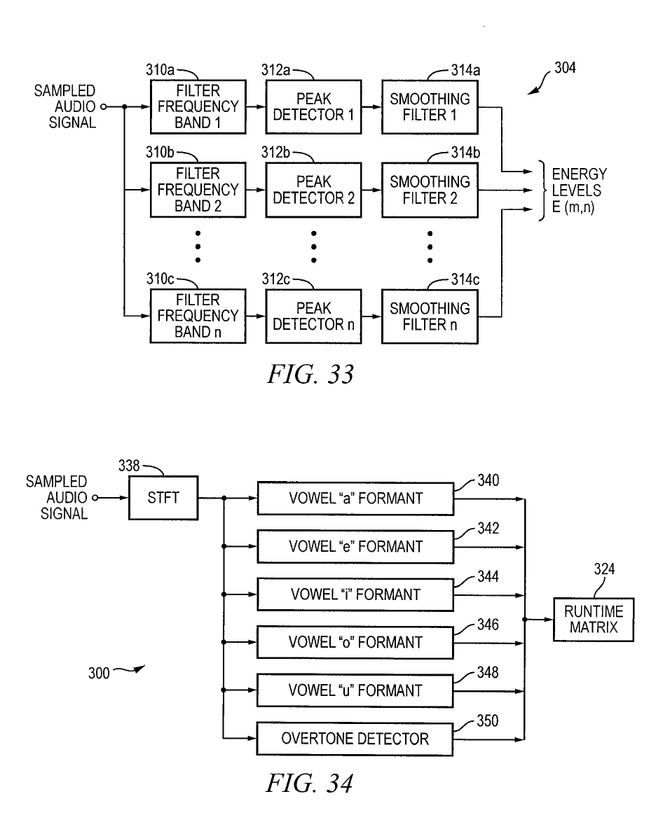

FIG. 32 illustrates further detail of time domain analysis block 302 including energy level isolation block 304 which isolates the energy level of each frame of the sampled audio signal 298 in multiple frequency bands. In FIG. 33, energy level isolation block 304 processes each frame of the sampled audio signal 298 in time sequence through filter frequency band 310a-310c to separate and isolate specific frequencies of the audio signal. The filter frequency bands 310a-310c can isolate specific frequency bands in the audio range 100-10000 Hz. In one embodiment, filter frequency band 310a is a bandpass filter with a pass band centered at 100 Hz, filter frequency band 310b is a bandpass filter with a pass band centered at 500 Hz, and filter frequency band 310c is a bandpass filter with a pass band centered at 1000 Hz. The output of filter frequency band 310a contains the energy level of the sampled audio signal 298 centered at 100 Hz. The output of filter frequency band 310b contains the energy level of the sampled audio signal 298 centered at 500 Hz. The output of filter frequency band 310c contains the energy level of the sampled audio signal 298 centered at 1000 Hz. The output of other filter frequency bands each contain the energy level of the sampled audio signal 298 for a given specific band. Peak detector 312a monitors and stores peak energy levels of the sampled audio signal 298 centered at 100 Hz. Peak detector 312b monitors and stores the peak energy levels of the sampled audio signal 298 centered at 500 Hz. Peak detector 312c monitors and stores the peak energy levels of the sampled audio signal 298 centered at 1000 Hz. Smoothing filter 314a removes spurious components and otherwise stabilizes the peak energy levels of the sampled audio signal 298 centered at 100 Hz. Smoothing filter 314b removes spurious components and otherwise stabilizes the peak energy levels of the sampled audio signal 298 centered at 500 Hz. Smoothing filter 314c removes spurious components of the peak energy levels and otherwise stabilizes the sampled audio signal 298 centered at 1000 Hz. The output of smoothing filters 314a-314c is the energy level function E(m,n) for each frame n in each frequency band 1-m of the sampled audio signal 298.

The time domain analysis block 302 of FIG. 26 also includes transient detector block 322, as shown in FIG. 32. Block 322 uses the energy function E(m,n) to track rapid or significant transient changes in energy levels over time indicating a change in sound content. The transient detector is a time domain parameter or characteristic of each frame n for all frequency bands 1-m and is stored as a value in runtime matrix 324 on a frame-by-frame basis.

Vibrato detector block 326 uses the energy function E(m,n) to track changes in amplitude of the energy levels over time indicating amplitude modulation associated with the vibrato effect. The vibrato detector is a time domain parameter or characteristic of each frame n for all frequency bands 1-m and is stored as a value in runtime matrix 324 on a frame-by-frame basis.

The frequency domain analysis block 300 in FIG. 26 includes STFT block 338, as shown in FIG. 34. Block 338 performs a time domain to frequency domain conversion on a frame-by-frame basis of the sampled audio signal 118 using a COLA) STFT or other FFT. The COLA STFT 338 performs time domain to frequency domain conversion using overlap analysis windows 299, as shown in FIG. 31b. The sampling windows 299 overlap by a predetermined number of samples of the audio signal, known as hop size, for additional sample points in the COLA STFT analysis to ensure that data is weighted equally in successive frames. Equation (2) provides a general format of the time domain to frequency domain conversion on the sampled audio signal 298.

Once the sampled audio signal 298 is in frequency domain, vowel “a” formant block 340 uses the frequency domain sampled audio signal to determine an occurrence of the vowel “a” in the sampled audio signal 298. Each vowel has a frequency designation. The vowel “a” occurs in the 800-1200 Hz range and no other frequency range. The vowel “a” formant parameter is value one if the vowel is present in the sampled audio signal 298 and value zero if the vowel is not present. The vowel “a” formant is a frequency domain parameter or characteristic of each frame n and is stored as a value in runtime matrix 324 on a frame-by-frame basis.

Vowel “e” formant block 342 uses the frequency domain sampled audio signal to determine an occurrence of the vowel “e” in the sampled audio signal 298. The vowel “e” occurs in the 400-600 Hz range and also in the 2200-2600 frequency range. The vowel “e” formant parameter is value one if the vowel is present in the sampled audio signal 298 and value zero if the vowel is not present. The vowel “e” formant is a frequency domain parameter or characteristic of each frame n and is stored as a value in runtime matrix 324 on a frame-by-frame basis.

Vowel “i” formant block 344 uses the frequency domain sampled audio signal to determine an occurrence of the vowel “i” in the sampled audio signal 298. The vowel “i” occurs in the 200-400 Hz range and also in the 3000-3500 frequency range. The vowel “i” formant parameter is value one if the vowel is present in the sampled audio signal 298 and value zero if the vowel is not present. The vowel “i” formant is a frequency domain parameter or characteristic of each frame n and is stored as a value in runtime matrix 324 on a frame-by-frame basis.

Vowel “o” formant block 346 uses the frequency domain sampled audio signal to determine an occurrence of the vowel “o” in the sampled audio signal 298. The vowel “o” occurs in the 400-600 Hz range and no other frequency range. The vowel “o” formant parameter is value one if the vowel is present in the sampled audio signal 298 and value zero if the vowel is not present. The vowel “o” formant is a frequency domain parameter or characteristic of each frame n and is stored as a value in runtime matrix 324 on a frame-by-frame basis.

Vowel “u” formant block 348 uses the frequency domain sampled audio signal to determine an occurrence of the vowel “u” in the sampled audio signal 298. The vowel “u” occurs in the 200-400 Hz range and no other frequency range. The vowel “u” formant parameter is value one if the vowel is present in the sampled audio signal 298 and value zero if the vowel is not present. The vowel “u” formant is a frequency domain parameter or characteristic of each frame n and is stored as a value in runtime matrix 324 on a frame-by-frame basis.

Overtone detector block 350 uses the frequency domain sampled audio signal to detect a higher harmonic resonance or overtone of the fundamental key, giving the impression of simultaneous tones. The overtone detector is a frequency domain parameter or characteristic of each frame n and is stored as a value in runtime matrix 324 on a frame-by-frame basis.

Runtime matrix 324 contains the time domain parameters determined in time domain analysis block 302 and the frequency domain parameters determined in frequency domain analysis block 300. Each time domain parameter and frequency domain parameter is a numeric parameter value PVn,j stored in runtime matrix 324 on a frame-by-frame basis, where n is the frame and j is the parameter, similar to Table 1. The time domain and frequency domain parameter values Pn,j are characteristic of specific frames and therefore useful in distinguishing between frames.

Returning to FIG. 29, database 292 is maintained in a memory component of audio amplifier 270 and contains a plurality of frame signature records 1, 2, 3, . . . i, with each frame signature having time domain parameters and frequency domain parameters corresponding to runtime matrix 324. In addition, the frame signature records 1-i contain weighting factors 1, 2, 3, . . . j for each time domain and frequency domain parameter, and a plurality of control parameters 1, 2, 3, . . . k.

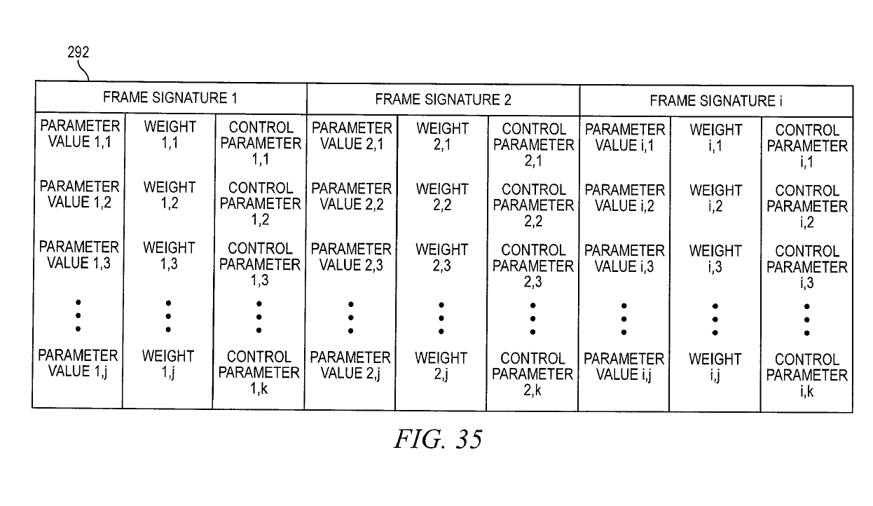

FIG. 35 shows database 292 with time domain and frequency domain parameters 1-j for each frame signature 1-i, weighting factors 1-j for each frame signature 1-i, and control parameters 1-k for each frame signature 1-i. Each frame signature record i is defined by the parameters 1-j, and associated weights 1-j, that are characteristic of the frame signature and will be used to identify an incoming frame from runtime matrix 324 as being best matched or most closely correlated to frame signature i. Once the incoming frame from runtime matrix 324 is matched to a particular frame signature i, adaptive intelligence control 294 uses control parameters 1-k for the matching frame signature to set the operating state of the signal processing blocks 272-284 of audio amplifier 270. For example, in a matching frame signature record i, control parameter i,1 sets the operating state of pre-filter block 272; control parameter i,2 sets the operating state of pre-effects block 274; control parameter i,3 sets the operating state of non-linear effects block 276; control parameter i,4 sets the operating state of user-defined modules 278; control parameter i,5 sets the operating state of post-effects block 280; control parameter i,6 sets the operating state of post-filter block 282; and control parameter i,7 sets the operating state of power amplification block 284.

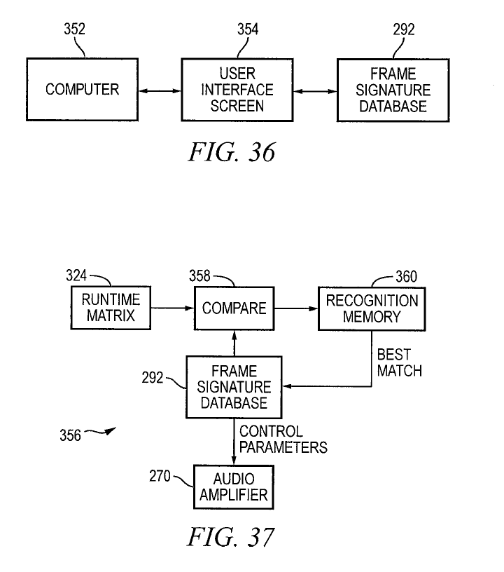

The time domain parameters and frequency domain parameters in frame signature database 292 contain values preset by the manufacturer, or entered by the user, or learned over time by playing an instrument. The factory or manufacturer of audio amplifier 270 can initially preset the values of time domain and frequency domain parameters 1-j, as well as weighting factors 1-j and control parameters 1-k. The user can change time domain and frequency domain parameters 1-j, weighting factors 1-j, and control parameters 1-k for each frame signature 1-i in database 292 directly using computer 352 with user interface screen or display 354, see FIG. 36. The values for time domain and frequency domain parameters 1-j, weighting factors 1-j, and control parameters 1-k are presented with interface screen 354 to allow the user to enter updated values.

In another, embodiment, time domain and frequency domain parameters 1-j, weighting factors 1-j, and control parameters 1-k can be learned by the artist singing into microphone 250. The artist sets audio amplifier 270 to a learn mode. The artist repetitively sings into microphone 250. The frequency domain analysis 300 and time domain analysis 302 of FIG. 30 create a runtime matrix 324 with associated frequency domain parameters and time domain parameters for each frame 1-n, as defined in FIG. 31a. The frequency domain parameters and time domain parameters for each frame 1-n are accumulated and stored in database 292.

The artist can make manual adjustments to audio amplifier 270 via front control panel 262. Audio amplifier 270 learns control parameters 1-k associated with the frame by the settings of the signal processing blocks 272-284 as manually set by the artist. When learn mode is complete, the frame signature records in database 292 are defined with the frame signature parameters being an average of the frequency domain parameters and time domain parameters accumulated in database 292, and an average of the control parameters 1-k taken from the manual adjustments of the signal processing blocks 272-284 of audio amplifier 270 in database 292. In one embodiment, the average is a root mean square of the series of accumulated frequency domain and time domain parameters 1-j and accumulated control parameters 1-k in database 292.

Weighting factors 1-j can be learned by monitoring the learned time domain and frequency domain parameters 1-j and increasing or decreasing the weighting factors based on the closeness or statistical correlation of the comparison. If a particular parameter exhibits a consistent statistical correlation, then the weight factor for that parameter can be increased. If a particular parameter exhibits a diverse statistical diverse correlation, then the weighting factor for that parameter can be decreased.

Once the parameters 1-j, weighting factors 1-j, and control parameters 1-k of frame signatures 1-i are established for database 292, the time domain and frequency domain parameters 1-j in runtime matrix 324 can be compared on a frame-by-frame basis to each frame signature 1-i to find a best match or closest correlation. In normal play mode, the artist sings lyrics to generate an audio signal having a time sequence of frames. For each frame, runtime matrix 324 is populated with time domain parameters and frequency domain parameters determined from a time domain analysis and frequency domain analysis of the audio signal, as described in FIGS. 29-34.

The time domain and frequency domain parameters 1-j for frame 1 in runtime matrix 324 and the parameters 1-j in each frame signature 1-i are compared on a one-by-one basis and the differences are recorded. FIG. 37 shows a recognition detector 356 with compare block 358 for determining the difference between time domain and frequency domain parameters 1-j for one frame in runtime matrix 324 and the parameters 1-j in each frame signature 1-i. For each parameter of frame 1, compare block 358 determines the difference between the parameter value in runtime matrix 324 and the parameter value in frame signature 1 and stores the difference in recognition memory 360. The differences between the parameters 1-j of frame 1 in runtime matrix 324 and the parameters 1-j of frame signature 1 are summed to determine a total difference value between the parameters 1-j of frame 1 and the parameters 1-j of frame signature 1.

Next, for each parameter of frame 1, compare block 358 determines the difference between the parameter value in runtime matrix 324 and the parameter value in frame signature 2 and stores the difference in recognition memory 360. The differences between the parameters 1-j of frame 1 in runtime matrix 324 and the parameters 1-j of frame signature 2 are summed to determine a total difference value between the parameters 1-j of frame 1 and the parameters 1-j of frame signature 2.

The time domain parameters and frequency domain parameters 1-j in runtime matrix 324 for frame 1 are compared to the time domain and frequency domain parameters 1-j in the remaining frame signatures 3-i in database 292, as described for frame signatures 1 and 2. The minimum total difference between the parameters 1-j of frame 1 of runtime matrix 324 and the parameters 1-j of frame signatures 1-i is the best match or closest correlation and the frame associated with frame 1 of runtime matrix 324 is identified with the frame signature having the minimum total difference between corresponding parameters. In this case, the time domain and frequency domain parameters 1-j of frame 1 in runtime matrix 324 are more closely aligned to the time domain and frequency domain parameters 1-j in frame signature 1.

With time domain parameters and frequency domain parameters 1-j of frame 1 in runtime matrix 324 matched to frame signature 1, adaptive intelligence control block 294 of FIG. 29 uses the control parameters 1-k associated with the matching frame signature 1 in database 292 to control operation of the signal processing blocks 272-284 of audio amplifier 270. The audio signal is processed through pre-filter block 272, pre-effects block 274, non-linear effects block 276, user-defined modules 278, post-effects block 280, post-filter block 282, and power amplification block 284, each operating as set by control parameter 1,1, control parameter 1,2, through control parameter 1,k of frame signature 1. The enhanced audio signal is routed to speaker 266 in enclosure 256. The listener hears the reproduced audio signal enhanced in realtime with characteristics determined by the dynamic content of the audio signal.

The time domain and frequency domain parameters 1-j for frame 2 in runtime matrix 324 and the parameters 1-j in each frame signature 1-i are compared on a one-by-one basis and the differences are recorded. For each parameter 1-j of frame 2, compare block 358 determines the difference between the parameter value in runtime matrix 324 and the parameter value in frame signature i and stores the difference in recognition memory 360. The differences between the parameters 1-j of frame 2 in runtime matrix 324 and the parameters 1-j of frame signature i are summed to determine a total difference value between the parameters 1-j of frame 2 and the parameters 1-j of frame signature i. The minimum total difference between the parameters 1-j of frame 2 of runtime matrix 324 and the parameters 1-j of frame signatures 1-i is the best match or closest correlation and the frame associated with frame 1 of runtime matrix 324 is identified with the frame signature having the minimum total difference between corresponding parameters. In this case, the time domain and frequency domain parameters 1-j of frame 2 in runtime matrix 324 are more closely aligned to the time domain and frequency domain parameters 1-j in frame signature 2. Adaptive intelligence control block 294 uses the control parameters 1-k associated with the matching frame signature 2 in database 292 to control operation of the signal processing blocks 272-284 of audio amplifier 270. The process continues for each frame n of runtime matrix 324.

In another embodiment, the time domain and frequency domain parameters 1-j for one frame in runtime matrix 324 and the parameters 1-j in each frame signature 1-i are compared on a one-by-one basis and the weighted differences are recorded. For each parameter of frame 1, compare block 358 determines the weighted difference between the parameter value in runtime matrix 324 and the parameter value in frame signature 1 as determined by weight 1,j and stores the weighted difference in recognition memory 360. The weighted differences between the parameters 1-j of frame 1 in runtime matrix 324 and the parameters 1-j of frame signature 1 are summed to determine a total weighted difference value between the parameters 1-j of frame 1 and the parameters 1-j of frame signature 1.

Next, for each parameter of frame 1, compare block 358 determines the weighted difference between the parameter value in runtime matrix 324 and the parameter value in frame signature 2 by weight 2,j and stores the weighted difference in recognition memory 360. The weighted differences between the parameters 1-j of frame 1 and the parameters 1-j of frame signature 2 are summed to determine a total weighted difference value between the parameters 1-j of frame 1 and the parameters 1-j of frame signature 2.

The time domain parameters and frequency domain parameters 1-j in runtime matrix 324 for frame 1 are compared to the time domain and frequency domain parameters 1-j in the remaining frame signatures 3-i in database 292, as described for frame signatures 1 and 2. The minimum total weighted difference between the parameters 1-j of frame 1 in runtime matrix 324 and the parameters 1-j of frame signatures 1-i is the best match or closest correlation and the frame associated with frame 1 of runtime matrix 324 is identified with the frame signature having the minimum total weighted difference between corresponding parameters. Adaptive intelligence control block 294 uses the control parameters 1-k in database 292 associated with the matching frame signature to control operation of the signal processing blocks 272-284 of audio amplifier 270.

The time domain and frequency domain parameters 1-j for frame 2 in runtime matrix 324 and the parameters 1-j in each frame signature 1-i are compared on a one-by-one basis and the weighted differences are recorded. For each parameter 1-j of frame 2, compare block 358 determines the weighted difference between the parameter value in runtime matrix 324 and the parameter value in frame signature i by weight i,j and stores the weighted difference in recognition memory 360. The weighted differences between the parameters 1-j of frame 2 in runtime matrix 324 and the parameters 1-j of frame signature i are summed to determine a total weighted difference value between the parameters 1-j of frame 2 and the parameters 1-j of frame signature i. The minimum total weighted difference between the parameters 1-j of frame 2 of runtime matrix 324 and the parameters 1-j of frame signatures 1-i is the best match or closest correlation and the frame associated with frame 1 of runtime matrix 324 is identified with the frame signature having the minimum total weighted difference between corresponding parameters. Adaptive intelligence control block 294 uses the control parameters 1-k in database 292 associated with the matching frame signature to control operation of the signal processing blocks 272-284 of audio amplifier 270. The process continues for each frame n of runtime matrix 324.

In another embodiment, a probability of correlation between corresponding parameters in runtime matrix 324 and frame signatures 1-i is determined. In other words, a probability of correlation is determined as a percentage that a given parameter in runtime matrix 324 is likely the same as the corresponding parameter in frame signature i. The percentage is a likelihood of a match. As described above, the time domain parameters and frequency domain parameters in runtime matrix 324 are stored on a frame-by-frame basis. For each frame n of each parameter j in runtime matrix 174 is represented by Pn,j=[Pn1, Pn2, . . . Pnj].

A probability ranked list R is determined between each frame n of each parameter j in runtime matrix 174 and each parameter j of each frame signature i. The probability value rᵢ can be determined by a root mean square analysis for the Pn,j and frame signature database Si,j in equation (3). The probability value R is (1−rᵢ)×100%. The overall ranking value for Pn,j and frame database Si,j is given in equation (4).

In some cases, the matching process identifies two or more frame signatures that are close to the present frame. For example, a frame in runtime matrix 324 may have a 52% probability that it matches to frame signature 1 and a 48% probability that it matches to frame signature 2. In this case, an interpolation is performed between the control parameter 1,1, control parameter 1,2 through control parameter 1,k and control parameter 2,1, control parameter 2,2, through control parameter 2,k, weighted by the probability of the match. The net effective control parameter 1 is 0.52*control parameter 1,1+0.48*control parameter 2,1. The net effective control parameter 2 is 0.52*control parameter 1,2+0.48*control parameter 2,2. The net effective control parameter k is 0.52*control parameter 1,k+0.48*control parameter 2,k. The net effective control parameters 1-k control operation of the signal processing blocks 272-284 of audio amplifier 270. The audio signal is processed through pre-filter block 272, pre-effects block 274, non-linear effects block 276, user-defined modules 278, post-effects block 280, post-filter block 282, and power amplification block 284, each operating as set by net effective control parameters 1-k. The audio signal is routed to speaker 266 in enclosure 256. The listener hears the reproduced audio signal enhanced in realtime with characteristics determined by the dynamic content of the audio signal.

While one or more embodiments of the present invention have been illustrated in detail, the skilled artisan will appreciate that modifications and adaptations to those embodiments may be made without departing from the scope of the present invention as set forth in the following claims.

What is claimed is:

1. An audio system, comprising a signal processor coupled for receiving an audio signal, wherein dynamic content of the audio signal controls operation of the signal processor.

2. The audio system of claim 1, further including:
a time domain processor coupled for receiving the audio signal and generating time domain parameters of the audio signal;
a frequency domain processor coupled for receiving the audio signal and generating frequency domain parameters of the audio signal;
a signature database including a plurality of signature records each having time domain parameters and frequency domain parameters and control parameters; and
a recognition detector for matching the time domain parameters and frequency domain parameters of the audio signal to a signature record of the signature database, wherein the control parameters of the matching signature record control operation of the signal processor.

3. The audio system of claim 1, wherein the signal processor includes a pre-filter, pre-effects, non-linear effects, user-defined module, post-effects, post-filter, or power amplification.

4. The audio system of claim 1, wherein the audio signal is sampled and the time domain processor and frequency domain processor operate on a plurality of frames of the sampled audio signal.

5. The audio system of claim 1, wherein the time domain processor or frequency domain processor detects onset of a note of the sampled audio signal.

6. The audio system of claim 1, wherein the time domain parameters include a note peak attack parameter, note peak release parameter, multiband peak attack parameter, multiband peak release parameter, slap detector parameter, tempo detector parameter, transient detector parameter, or vibrato detector parameter.

7. The audio system of claim 1, wherein the frequency domain parameters include a harmonic attack ratio parameter, harmonic release ratio parameter, open and mute factor parameter, neck and bridge factor parameter, pitch detector parameter, vowel formant parameter, or overtone detector parameter.

8. The audio system of claim 1, wherein the audio signal is generated by a guitar.

9. The audio system of claim 1, wherein the audio signal is generated by vocals.

10. A method of controlling an audio system, comprising:
providing a signal processor adapted for receiving an audio signal; and
controlling operation of the signal processor using dynamic content of the audio signal.

11. The method of claim 10, further including:
generating time domain parameters of the audio signal;
generating frequency domain parameters of the audio signal;
providing a signature database including a plurality of signature records each having time domain parameters and frequency domain parameters and control parameters;
matching the time domain parameters and frequency domain parameters of the audio signal to a signature record of the signature database; and
controlling operation of the signal processor based on the control parameters of the matching signature record.

12. The method of claim 10, wherein the signal processor includes a pre-filter, pre-effects, non-linear effects, user-defined module, post-effects, post-filter, or power amplification.

13. The method of claim 10, further including:
sampling the audio signal; and
generating the time domain parameters and frequency domain parameters based on a plurality of frames of the sampled audio signal.

14. The method of claim 10, further including detecting an onset of a note of the sampled audio signal.

15. The method of claim 10, wherein the time domain parameters include a note peak attack parameter, note peak release parameter, multiband peak attack parameter, multiband peak release parameter, slap detector parameter, tempo detector parameter, transient detector parameter, or vibrato detector parameter.

16. The method of claim 10, wherein the frequency domain parameters include a harmonic attack ratio parameter, harmonic release ratio parameter, open and mute factor parameter, neck and bridge factor parameter, pitch detector parameter, vowel formant parameter, or overtone detector parameter.

17. The method of claim 10, further including generating the audio signal with a guitar or vocals.

18. An audio system, comprising:
a signal processor coupled for receiving an audio signal;
a time domain processor coupled for receiving the audio signal and generating time domain parameters of the audio signal;
a frequency domain processor coupled for receiving the audio signal and generating frequency domain parameters of the audio signal;
a signature database including a plurality of signature records each having time domain parameters and frequency domain parameters and control parameters; and
a recognition detector for matching the time domain parameters and frequency domain parameters of the audio signal to a signature record of the signature database, wherein the control parameters of the matching signature record control operation of the signal processor.

19. The audio system of claim 18, wherein the signal processor includes a pre-filter, pre-effects, non-linear effects, user-defined module, post-effects, post-filter, or power amplification.

20. The audio system of claim 18, wherein the audio signal is sampled and the time domain processor and frequency domain processor operate on a plurality of frames of the sampled audio signal.

21. The audio system of claim 18, wherein the time domain processor or frequency domain processor detects onset of a note of the sampled audio signal.

22. The audio system of claim 18, wherein the time domain parameters include a note peak attack parameter, note peak release parameter, multiband peak attack parameter, multiband peak release parameter, slap detector parameter, tempo detector parameter, transient detector parameter, or vibrato detector parameter.

23. The audio system of claim 18, wherein the frequency domain parameters include a harmonic attack ratio parameter, harmonic release ratio parameter, open and mute factor parameter, neck and bridge factor parameter, pitch detector parameter, vowel formant parameter, or overtone detector parameter.

24. The audio system of claim 18, wherein the audio signal is generated by a guitar or vocals.

25. A method of controlling an audio system, comprising:
providing a signal processor adapted for receiving an audio signal;
generating time domain parameters of the audio signal;
generating frequency domain parameters of the audio signal;
providing a signature database including a plurality of signature records each having time domain parameters and frequency domain parameters and control parameters;
matching the time domain parameters and frequency domain parameters of the audio signal to a signature record of the signature database; and
controlling operation of the signal processor based on the control parameters of the matching signature record.

26. The method of claim 25, wherein the signal processor includes a pre-filter, pre-effects, non-linear effects, user-defined module, post-effects, post-filter, or power amplification.

27. The method of claim 25, further including:
sampling the audio signal; and
generating the time domain parameters and frequency domain parameters based on a plurality of frames of the sampled audio signal.

28. The method of claim 25, further including detecting an onset of a note of the sampled audio signal.

29. The method of claim 25, wherein the time domain parameters include a note peak attack parameter, note peak release parameter, multiband peak attack parameter, multiband peak release parameter, slap detector parameter, tempo detector parameter, transient detector parameter, or vibrato detector parameter.

30. The method of claim 25, wherein the frequency domain parameters include a harmonic attack ratio parameter, harmonic release ratio parameter, open and mute factor parameter, neck and bridge factor parameter, pitch detector parameter, vowel formant parameter, or overtone detector parameter.

31. The method of claim 25, further including generating the audio signal with a guitar or vocals.
